(19) United States
(12) Patent Application Publication
(10) Pub. No.: US 2025/0314966 A1
(43) Pub. Date: Oct. 9, 2025

(54) RESIST PATTERN FORMING PROCESS

(71) Applicant: Shin-Etsu Chemical Co., Ltd., Tokyo (JP)

(72) Inventors: Shun Kikuchi, Joetsu-shi (JP); Satoshi Kusama, Joetsu-shi (JP); Kousuke Ohyama, Joetsu-shi (JP); Masaki Ohashi, Joetsu-shi (JP)

(73) Assignee: Shin-Etsu Chemical Co., Ltd., Tokyo (JP)

(21) Appl. No.: 19/090,605

(22) Filed: Mar. 26, 2025

(30) Foreign Application Priority Data
Apr. 3, 2024 (JP) 2024-059982

(51) Int. Cl. G03F 7/029; G03F 7/36

(52) U.S. Cl. CPC G03F 7/0295; G03F 7/36

(57) ABSTRACT

A resist pattern is formed by (i) applying a resist composition comprising a hypervalent iodine compound, a carboxylic acid, and a solvent onto a substrate or an underlying film to form a resist film, (ii) exposing the resist film to high-energy radiation, (iii) baking the exposed resist film, and (iv) dry etching the baked resist film for development.

### CROSS-REFERENCE TO RELATED APPLICATIONS

This non-provisional application claims priority under 35 U.S.C. § 119 (a) on Patent Application No. 2024-059982 filed in Japan on Apr. 3, 2024, the entire contents of which are hereby incorporated by reference.

### TECHNICAL FIELD

This invention relates to a resist pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the resist developing step in the semiconductor fabrication process, the wet process, i.e., wet development using an alkaline aqueous solution or organic solvent as the developer is mainly adopted at the present. As the pattern feature size is further reduced, however, the influences of pattern swell and surface tension of the liquid become noticeable during the development by the wet process.

For the resist development, the dry process, i.e., dry development using the etching step with the aid of plasma is also known. The development by the dry process eliminates the influences of pattern swell and surface tension of the liquid. Therefore the effort to change the resist development step to a dry one has been made from long ago.

Patent Document 1 describes a chemically amplified positive resist composition comprising a specific resin component. The steps of forming a resist film, exposing the resist film and post-exposure bake (PEB) are carried out as in the conventional wet process until the development step. Only the development step is carried out on a dry basis. A positive tone pattern is formed at a high resolution.

Chemically amplified resist compositions have the problem that as the feature size is reduced, image blurs due to acid diffusion become significant (see Non-Patent Document 1). To insure resolution for fine patterns with a feature size of 45 nm et seq., not only an improvement in dissolution contrast is requisite as in the prior art, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of PEB fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition. It would be desirable to have a non-chemically amplified resist composition.

A typical non-chemically amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of their application to the resist at a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 2 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. Particularly in the case of line-and-space patterns, chances of collapse and disconnection of patterns increase outstandingly as the pattern size becomes smaller. Minimizing such chances leads to an improvement in maximum resolution.

Patent Document 3 discloses a negative resist composition comprising a tin compound. It is described that this resist composition allows for development by the dry process. Based on tin element having high EUV absorption, this resist composition is improved in stochastics. Since the dry process eliminates the influences of pattern swell and surface tension of the liquid, a high sensitivity and high resolution are achievable. The so-called metal resist compositions, however, suffer from many problems including poor shelf stability and defectiveness due to post-etching residues. Further, the metal resist compositions are mainly of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2023-157346
Patent Document 2: JP-A 2018-005224 (U.S. Pat. No. 10,323,113)
Patent Document 3: JP-A 2022-538040
Non-Patent Document 1: SPIE Vol. 5039 p1 (2003)
Non-Patent Document 2: SPIE Vol. 6520 p65203L-1 (2007)

### SUMMARY OF THE INVENTION

An object of the invention is to provide a resist pattern forming process using a non-chemically-amplified resist composition which exhibits a high sensitivity and maximum resolution when processed by photolithography using high-energy radiation, typically EB and EUV lithography, wherein a resist film after exposure is developed by dry etching, for thereby forming a positive or negative tone resist pattern.

The inventors have found that a resist composition based on a specific hypervalent iodine compound and a carboxylic acid has a very high sensitivity and forms a resist film having a satisfactory resolution, and that when a resist film of the resist composition is developed by dry etching, a positive or negative tone resist pattern of satisfactory profile is formed. The resist composition and the process are thus quite useful in precise micropatterning.

In one aspect, the invention provides a resist pattern forming process comprising the steps of:
(i) applying a resist composition onto a substrate or a substrate having an underlying film deposited thereon to form a resist film thereon, the resist composition comprising at least one hypervalent iodine compound selected from a hypervalent iodine compound having the formula (1) and a hypervalent iodine compound having the formula (2), a carboxylic acid, and a solvent,
(ii) exposing the resist film to high-energy radiation,
(iii) baking the exposed resist film, and
(iv) dry etching the baked resist film for development to form a resist pattern.

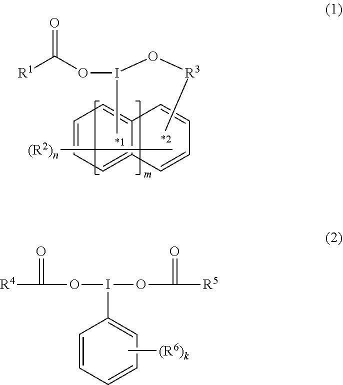

Herein m is 0 or 1, n is an integer of 0 to 4 when m=0 and an integer of 0 to 6 when m=1, k is an integer of 0 to 5,
R¹ is halogen or a C₁-C₁₀ hydrocarbyl group which may contain a heteroatom,
R² is halogen or a C₁-C₄₀ hydrocarbyl group which may contain a heteroatom; when n is 2 or more, a plurality of R² may be identical or different and a plurality of R² may bond together to form a ring with the carbon atoms on the aromatic ring to which they are attached,
R³ is carbonyl or a C₁-C₁₀ hydrocarbylene group which may contain a heteroatom,
*1 and *2 each designate a point of attachment to the carbon atom on the aromatic ring in the formula, *1 and *2 are attached to vicinal carbon atoms on the aromatic ring,
R⁴ and R⁵ are each independently halogen or a C₁-C₁₀ hydrocarbyl group which may contain a heteroatom, R⁴ and R⁵ may bond together to form a ring with the carbon atoms to which they are attached and the intervenient atoms, and
R⁶ is halogen or a C₁-C₄₀ hydrocarbyl group which may contain a heteroatom; when k is 2, 3, 4 or 5, a plurality of R⁶ may be identical or different and a plurality of R⁶ may bond together to form a ring with the carbon atoms on the aromatic ring to which they are attached.

In a preferred embodiment, the carboxylic acid has the formula (3).

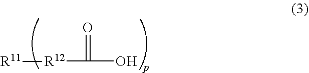

Herein p is an integer of 1 to 4,
R¹¹ is a C₁-C₄₀ p-valent hydrocarbon group or C₂-C₄₀ p-valent heterocyclic group, R¹¹ may also be an ether bond, carbonyl group, azo group, thioether bond, carbonate bond, carbamate bond, sulfinyl group or sulfonyl group when p=2, some or all of the hydrogen atoms in the p-valent hydrocarbon group or p-valent heterocyclic group may be substituted by a heteroatom-containing moiety, and some —CH₂— in the p-valent hydrocarbon group may be replaced by a heteroatom-containing moiety,
R¹² is a single bond or C₁-C₂₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety, and a plurality of R¹² may be identical or different when p=2, 3 or 4.

In a preferred embodiment, the high-energy radiation is i-line, KrF excimer laser, ArF excimer laser, EB or EUV.

In a preferred embodiment, the dry etching step (iv) is carried out using a gas containing at least one of oxygen and tetrafluoromethane.

### Advantageous Effects of Invention

The resist composition exhibits both high sensitivity and resolution when processed by lithography using i-line, KrF excimer laser, ArF excimer laser, EB or EUV and developed by dry etching. The resist composition is quite useful in micropatterning.

### DETAILED DESCRIPTION OF THE INVENTION

The terms “a” and “an” herein do not denote a limitation of quantity, but rather denote the presence of at least one of the referenced item. As used herein, the notation (Cₙ-Cₘ) means a group containing from n to m carbon atoms per group. Me stands for methyl.

The abbreviations and acronyms have the following meaning.
UV: ultraviolet radiation
EUV: extreme ultraviolet
EB: electron beam
Mw: weight average molecular weight
Mw/Mn: polydispersity index
GPC: gel permeation chromatography
PAB: post-apply bake
PEB: post-exposure bake
LWR: line width roughness
CDU: critical dimension uniformity

### [Resist Composition]

The resist pattern forming process of the invention uses a resist composition comprising a specific hypervalent iodine compound, a carboxylic acid, and a solvent.

### [Hypervalent Iodine Compound]

The hypervalent iodine compound is a three-coordinate hypervalent iodine compound having the formula (1) or (2).

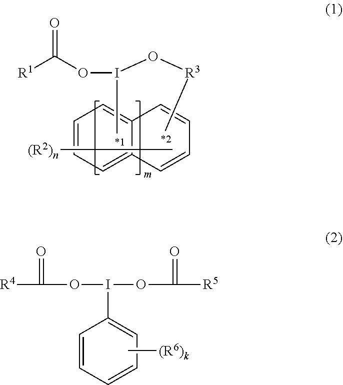

In formula (1), m is 0 or 1. The subscript n is an integer of 0 to 4 when m=0 and an integer of 0 to 6 when m=1. The subscript n is preferably 0, 1, 2, 3 or 4, more preferably 0, 1, 2 or 3, even more preferably 0, 1 or 2, most preferably 0 or 1.

In formula (1), R¹ is halogen or a C₁-C₁₀ hydrocarbyl group which may contain a heteroatom. Suitable halogen atoms include fluorine, chlorine, bromine and iodine. The C₁-C₁₀ hydrocarbyl group may be saturated or unsaturated and straight, branched or cyclic. Examples thereof include C₁-C₁₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl, C₂-C₁₀ alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ is preferably a C₁-C₄ hydrocarbyl group or C₁-C₄ fluorinated hydrocarbyl group, more preferably a C₁-C₄ hydrocarbyl group.

In formula (1), R² is halogen or a C₁-C₄₀ hydrocarbyl group which may contain a heteroatom. Suitable halogen atoms include fluorine, chlorine, bromine and iodine. The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). When n is 2 or more, a plurality of R² may be identical or different and a plurality of R² may bond together to form a ring with the carbon atoms on the aromatic ring to which they are attached.

In formula (1), R³ is carbonyl or a C₁-C₁₀ hydrocarbylene group which may contain a heteroatom. The C₁-C₁₀ hydrocarbylene group may be saturated or unsaturated and straight, branched or cyclic. Examples thereof include C₁-C₁₀ alkylene groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 2-methylpropane-1,2-diyl, pentane-1,5-diyl, hexane-1,6-diyl, heptane-1,7-diyl, octane-1,8-diyl, nonane-1,9-diyl, and decane-1,10-diyl; C₃-C₁₀ cyclic saturated hydrocarbylene groups such as cyclopentanediyl, cyclohexanediyl, norbornanediyl, adamantanediyl, and tricyclo[5.2.1.0^{2,6}]decanediyl; C₂-C₁₀ alkenylene groups such as vinylene and propynylene; C₆-C₁₀ arylene groups such as phenylene, methylphenylene, ethylphenylene, n-propylphenylene, isopropylphenylene, n-butylphenylene, and naphthylene; and combinations thereof. In the hydrocarbylene group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, haloalkyl, halogen, carbonyl moiety, ether bond, thioether bond, ester bond, sulfonate ester bond, carbonate bond, carbamate bond, lactone ring, sultone ring, or carboxylic anhydride (—C(═O)—O—C(═O)—). R³ is preferably carbonyl, a C₁-C₄ hydrocarbylene group or C₁-C₄ fluorinated hydrocarbylene group.

In formula (1), *1 and *2 each designate a point of attachment to the carbon atom on the aromatic ring in the formula, with the proviso that *1 and *2 are attached to vicinal carbon atoms on the aromatic ring. It is contemplated that the combination of *1 and *2 with m includes the following four patterns.

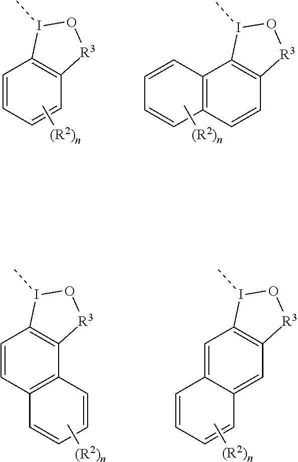

Herein n, R² and R³ are as defined above. The broken line designates a point of attachment to R¹—C(═O)—O—.

In formula (2), k is an integer of 0 to 5.

In formula (2), R⁴ and R⁵ are each independently halogen or a C₁-C₁₀ hydrocarbyl group which may contain a heteroatom. R⁴ and R⁵ may bond together to form a ring with the carbon atoms to which they are attached and the intervenient atoms. Suitable halogen atoms include fluorine, chlorine, bromine and iodine. The C₁-C₁₀ hydrocarbyl group may be saturated or unsaturated and straight, branched or cyclic. Examples thereof include C₁-C₁₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl, C₂-C₁₀ alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R⁴ and R⁵ each are preferably a C₁-C₄ hydrocarbyl group or C₁-C₄ fluorinated hydrocarbyl group, more preferably a C₁-C₄ hydrocarbyl group.

In formula (2), R⁶ is halogen or a C₁-C₄₀ hydrocarbyl group which may contain a heteroatom. When k is 2, 3, 4 or 5, a plurality of R⁶ may be identical or different and a plurality of R⁶ may bond together to form a ring with the carbon atoms on the aromatic ring to which they are attached. Suitable halogen atoms include fluorine, chlorine, bromine and iodine. The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl, C₂-C₄₀ alkenyl groups such as vinyl and allyl, C₆-C₄₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R⁶ is preferably a C₁-C₄ hydrocarbyl group.

Examples of the hypervalent iodine compound having formula (1) are shown below, but not limited thereto.

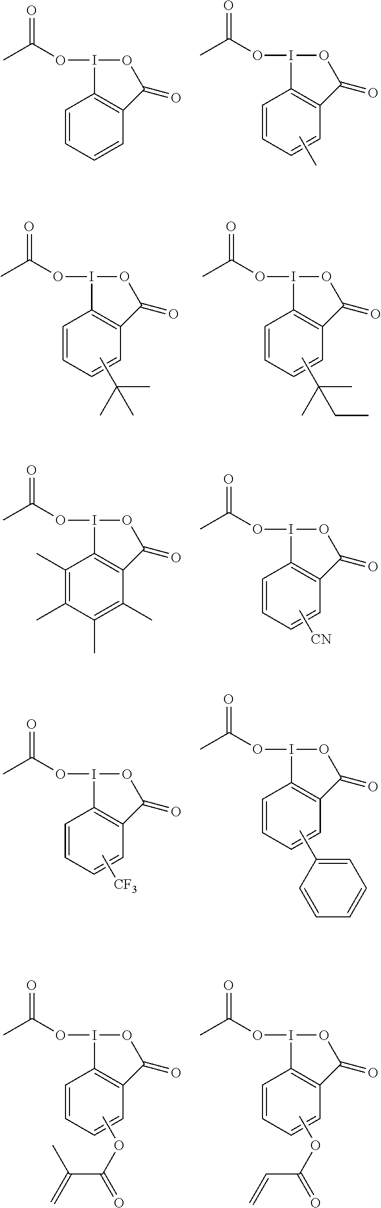

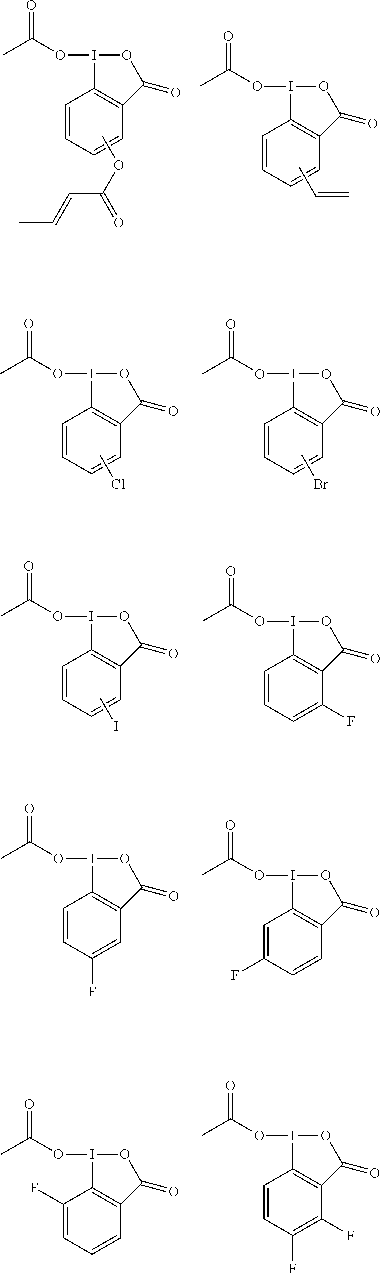

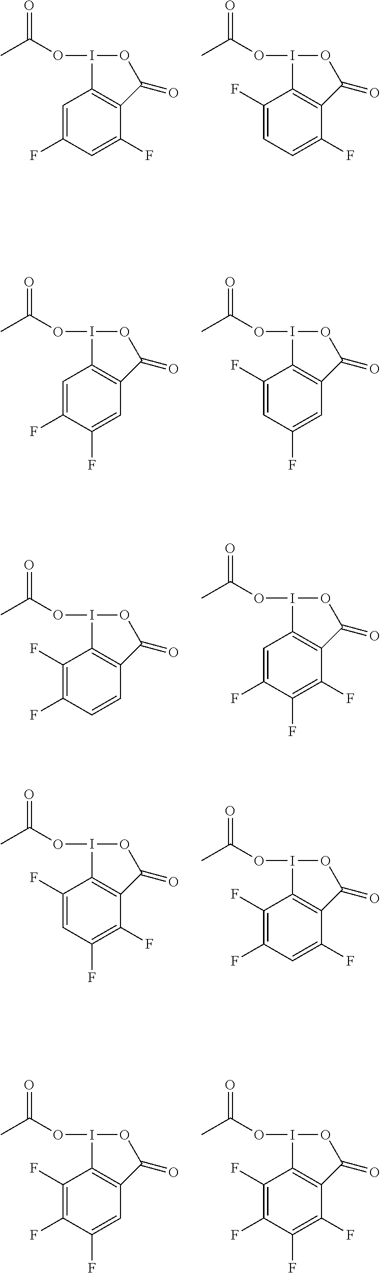

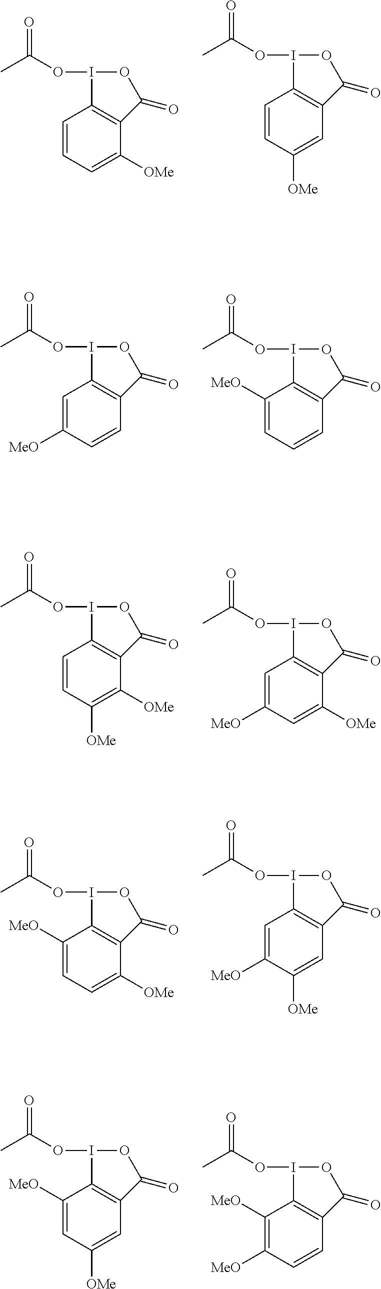

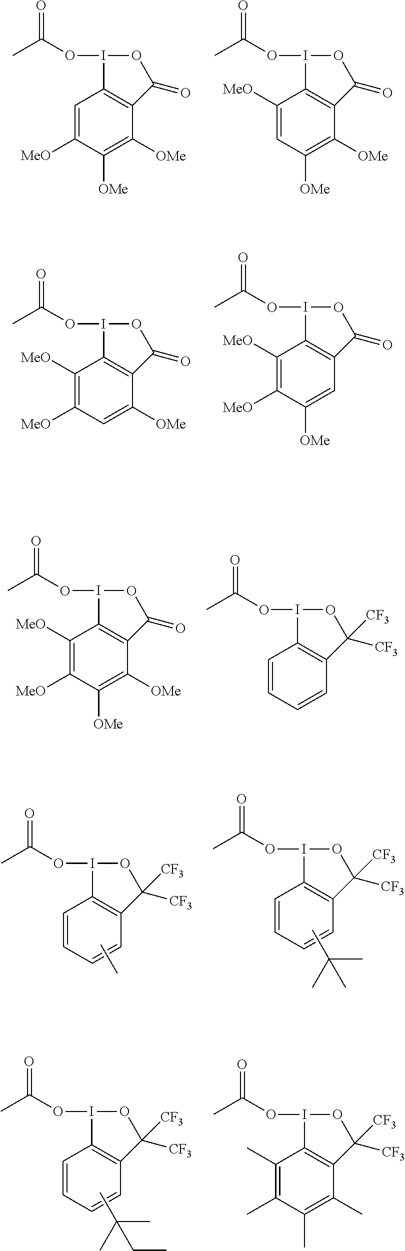

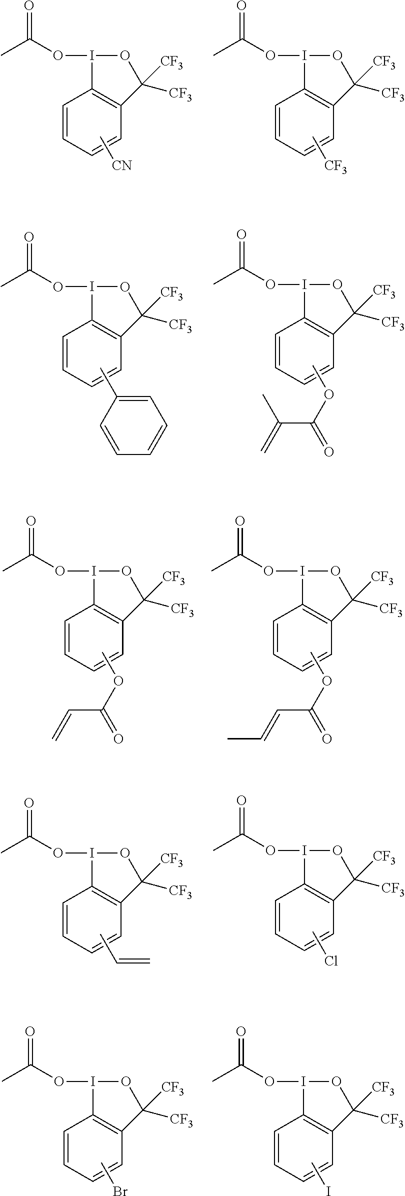

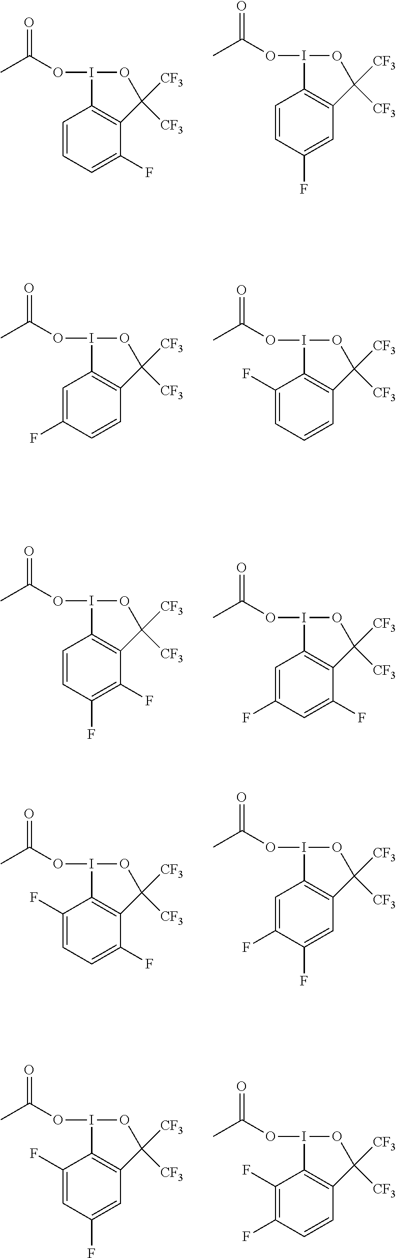

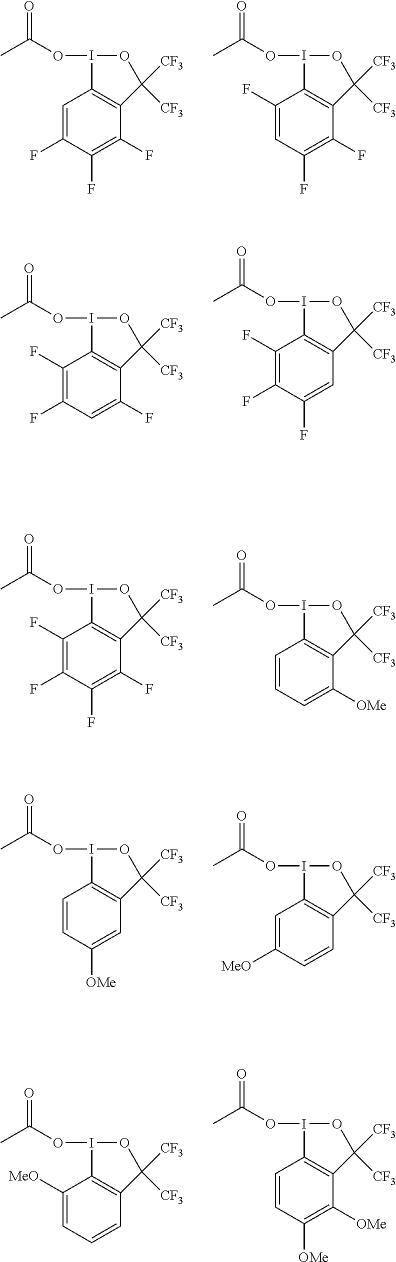

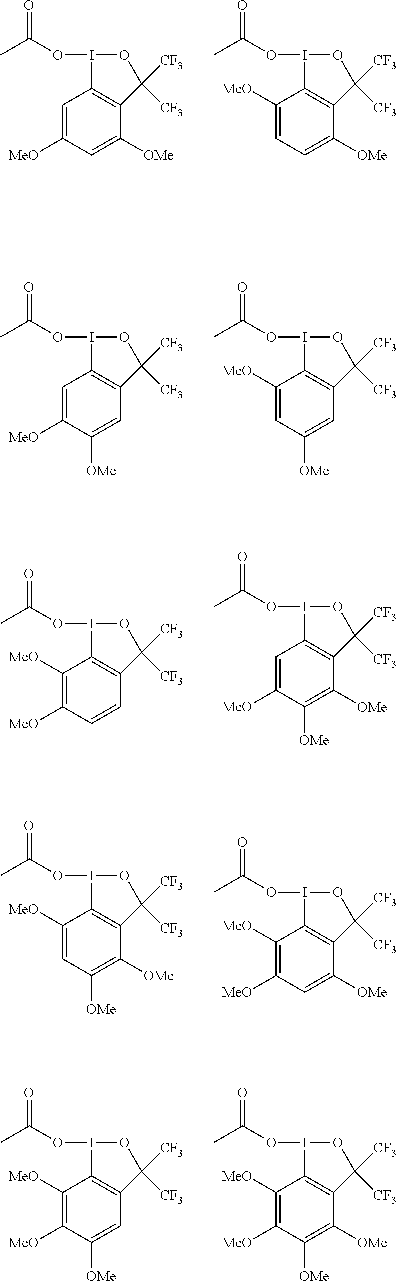

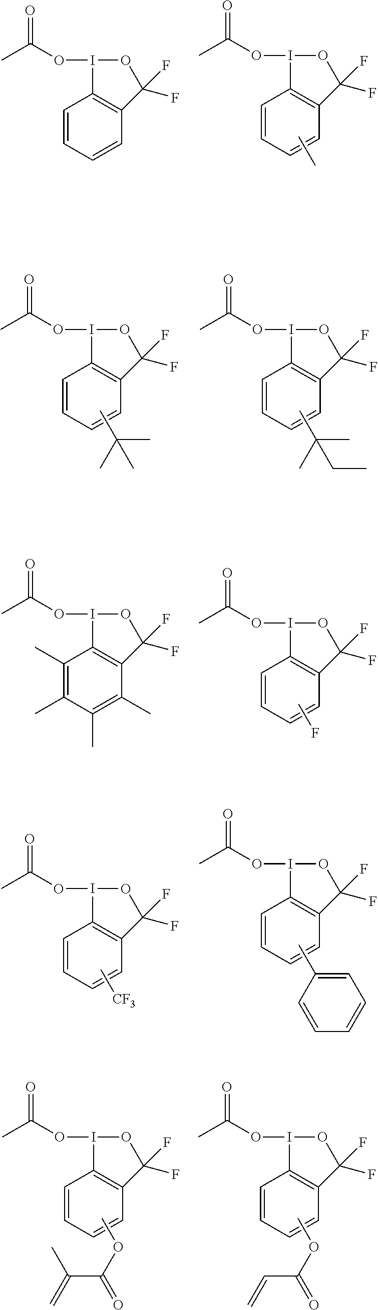

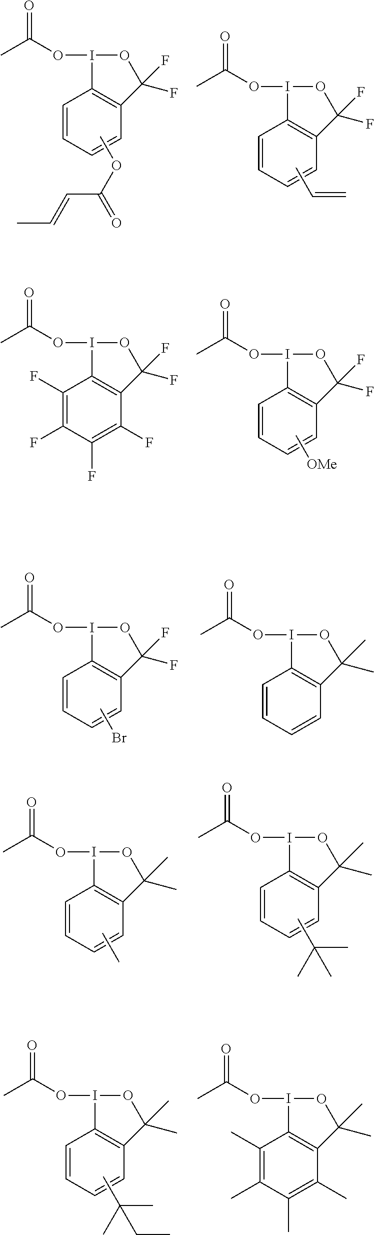

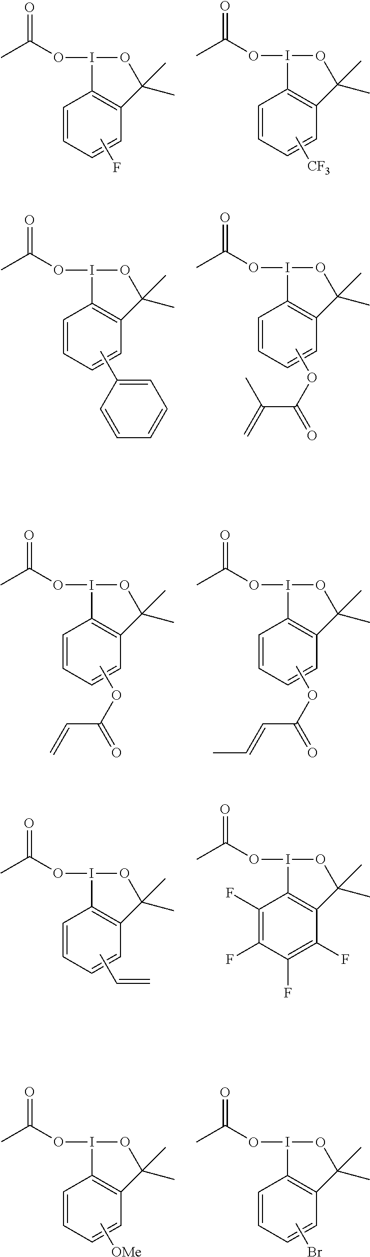

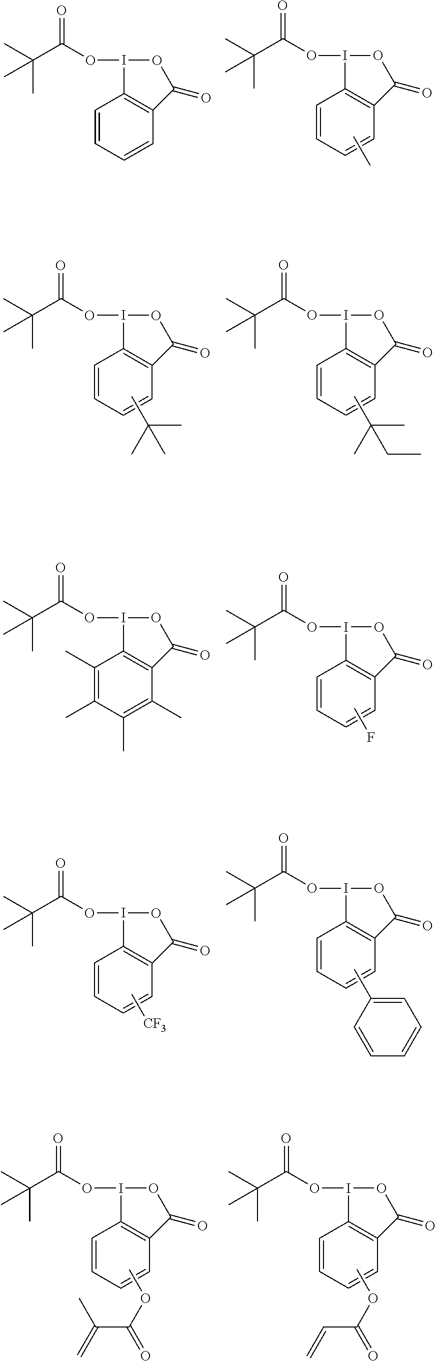

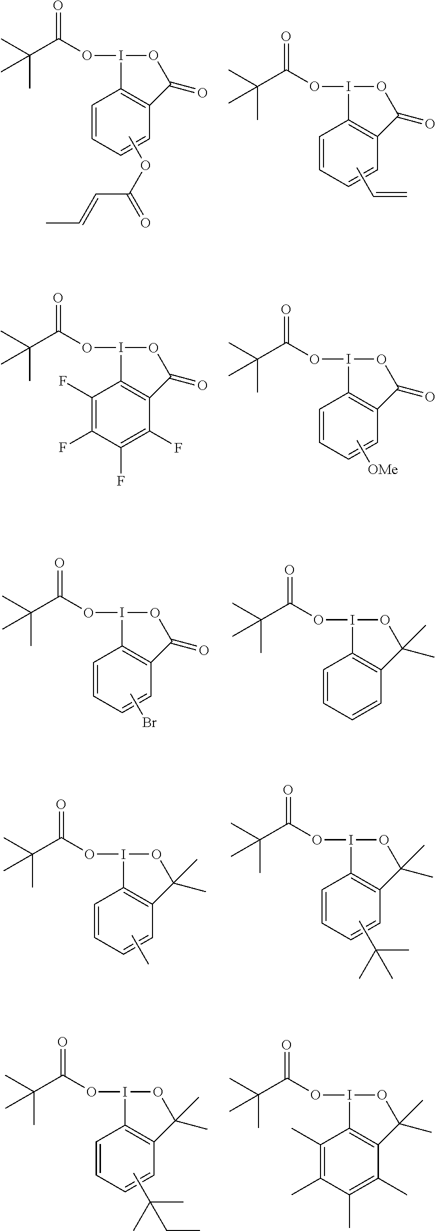

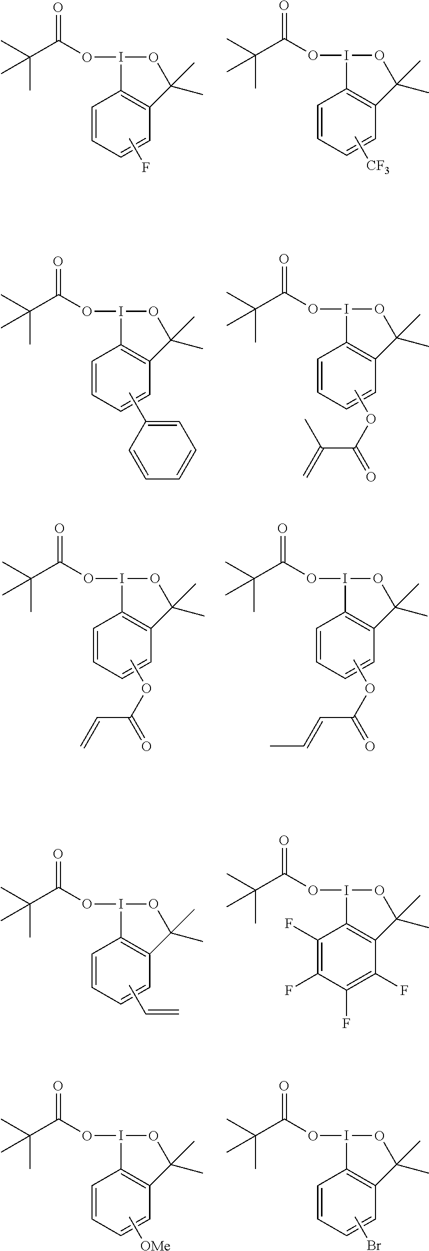

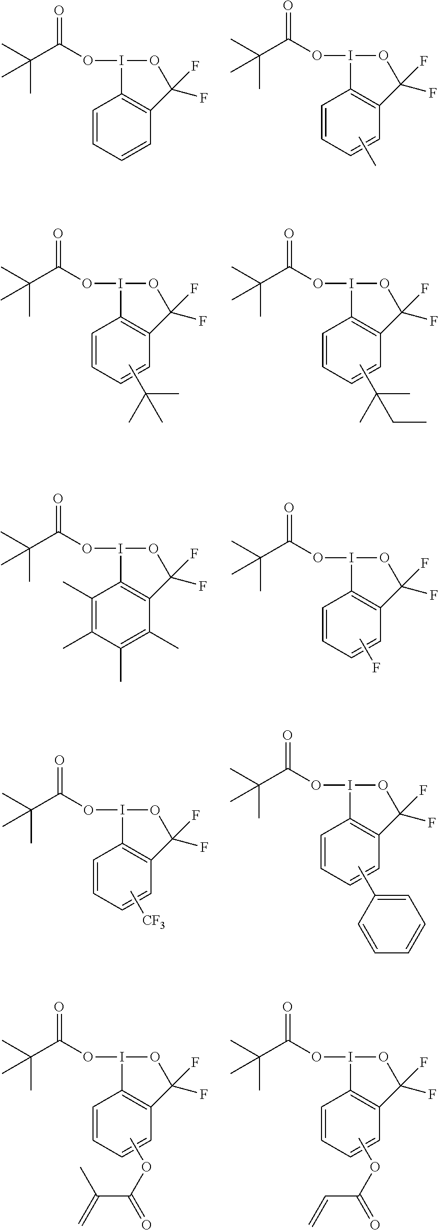

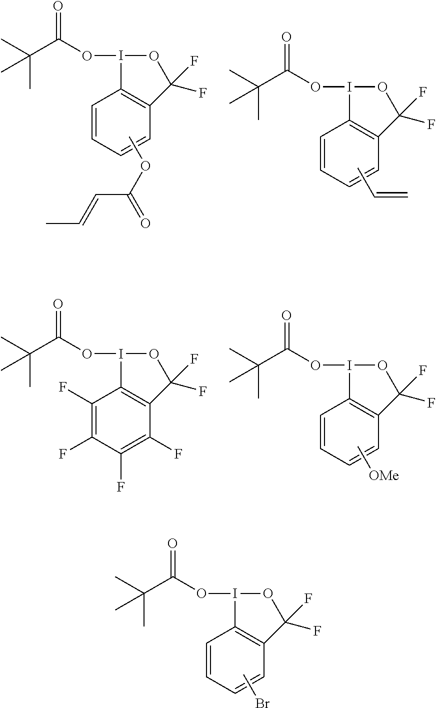

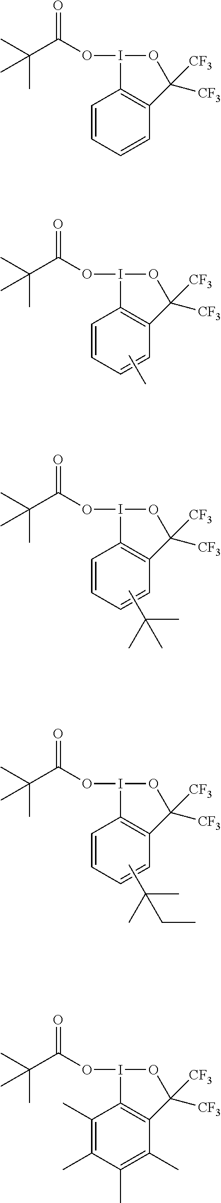

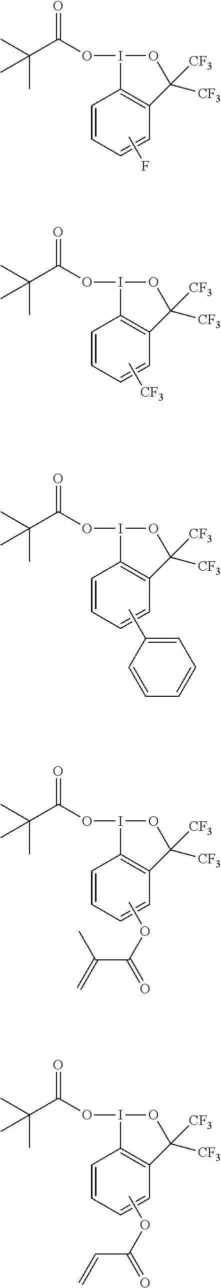

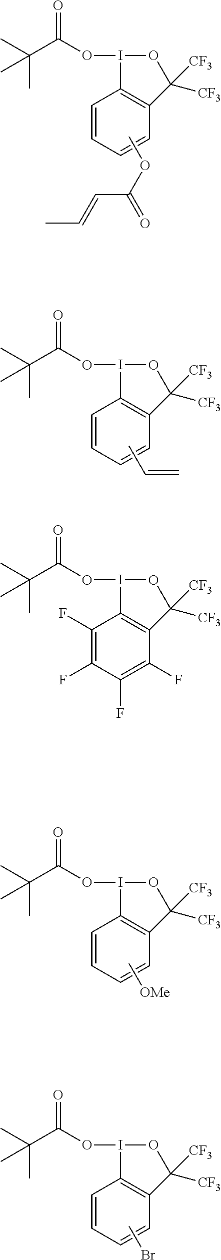

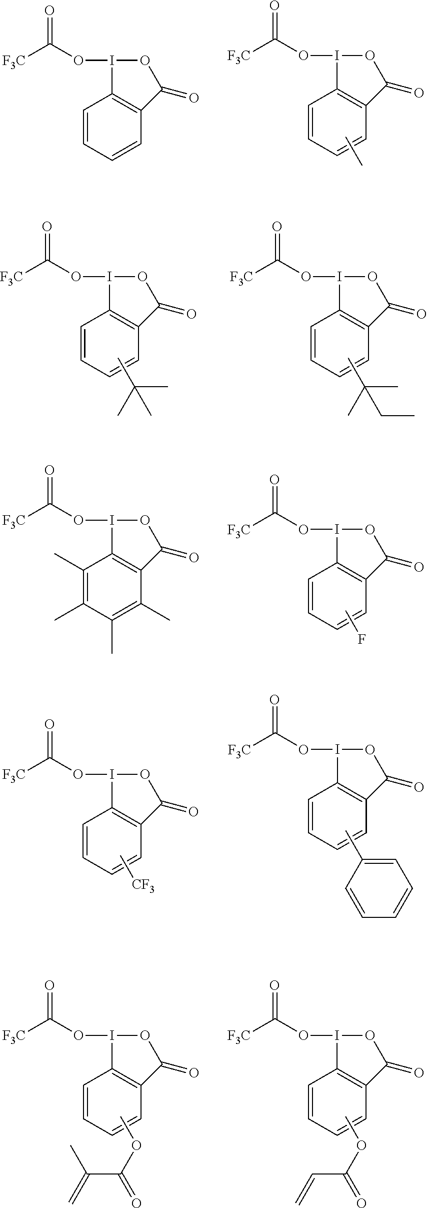

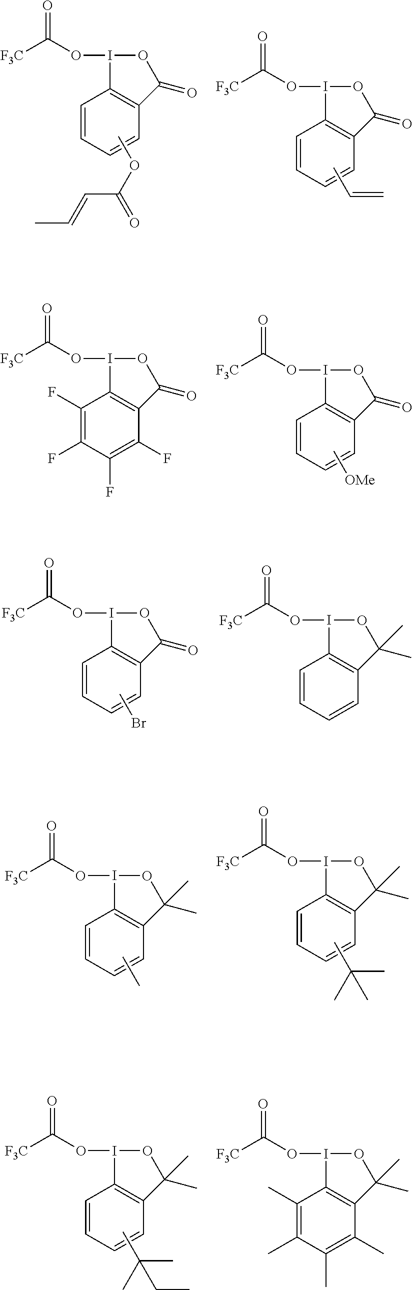

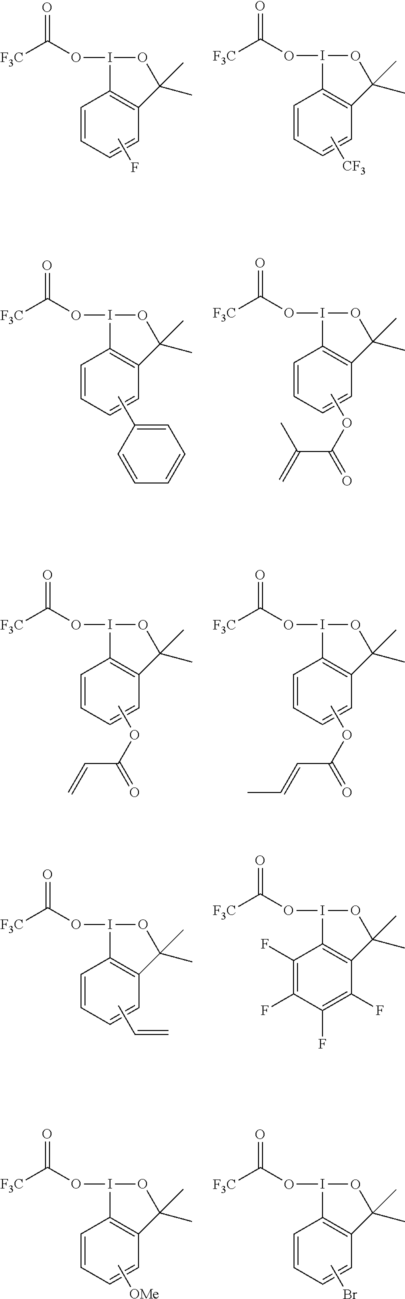

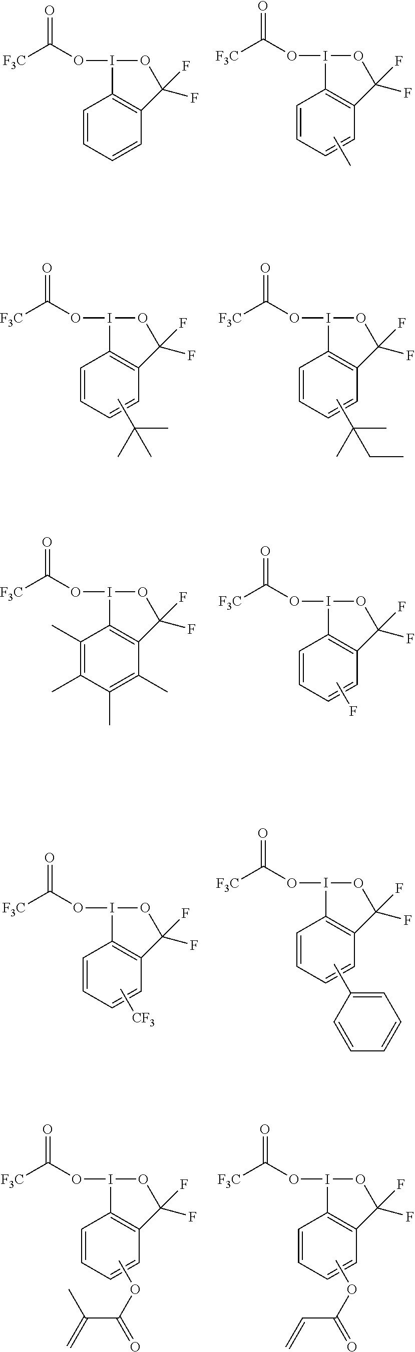

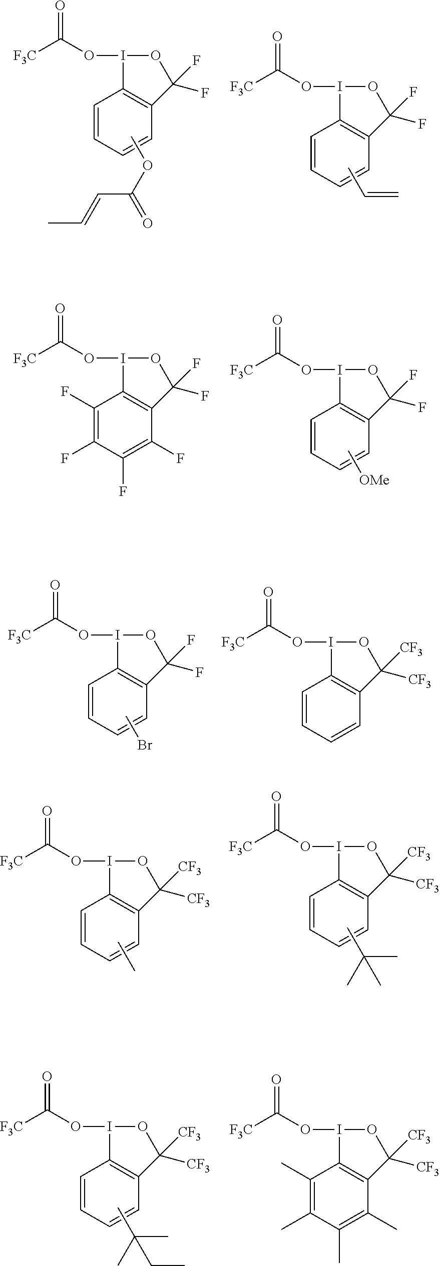

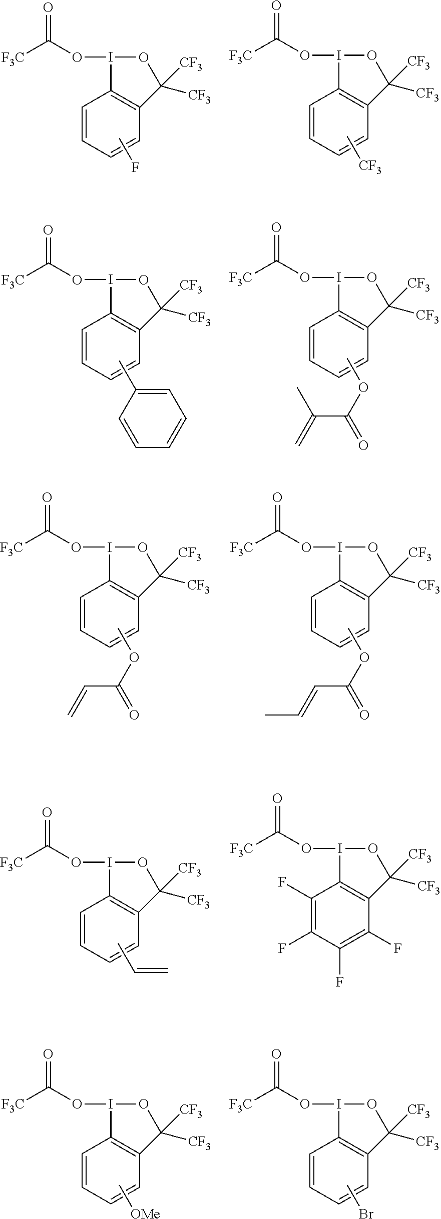

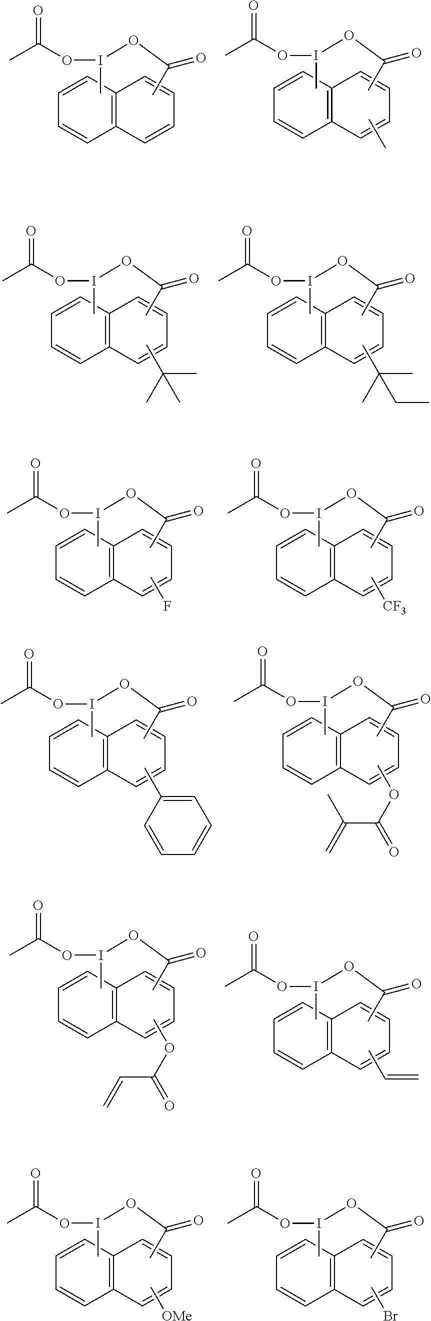

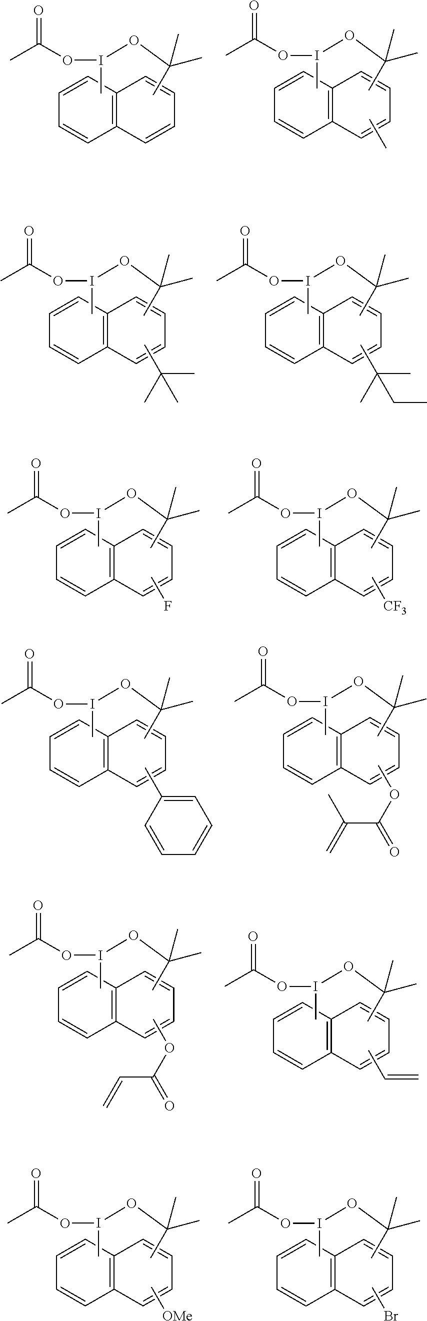

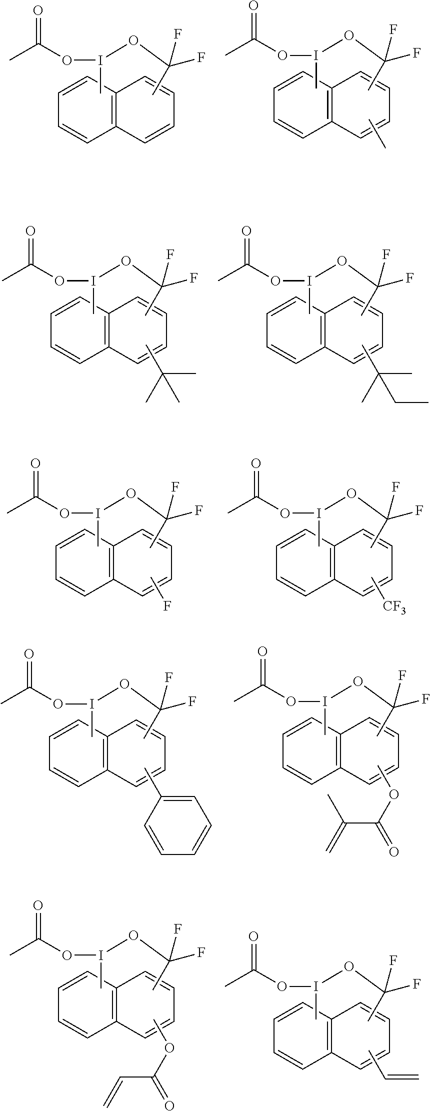

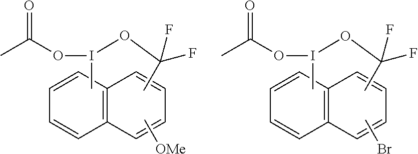

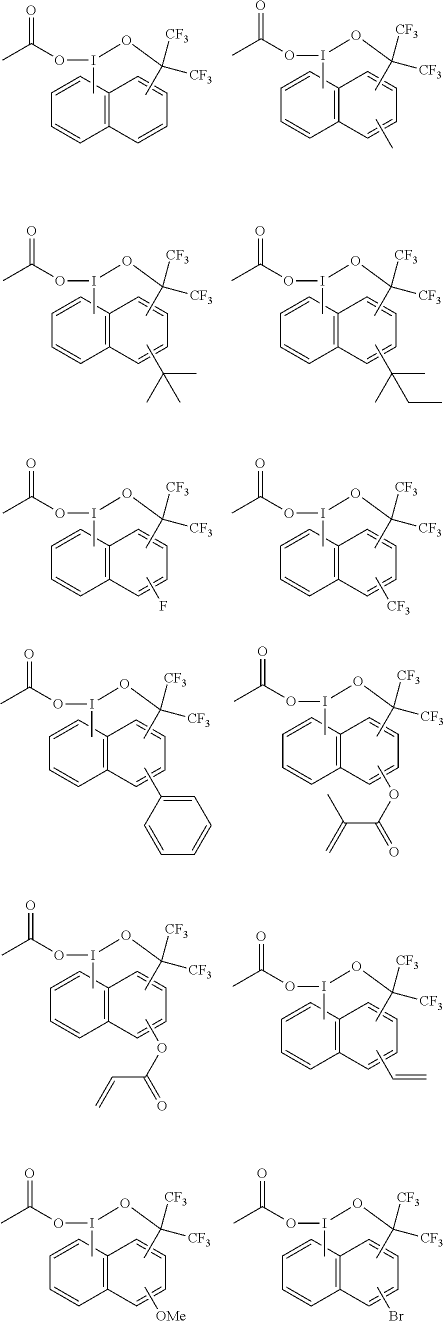

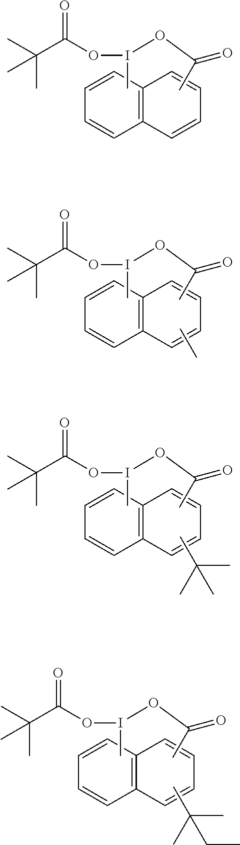

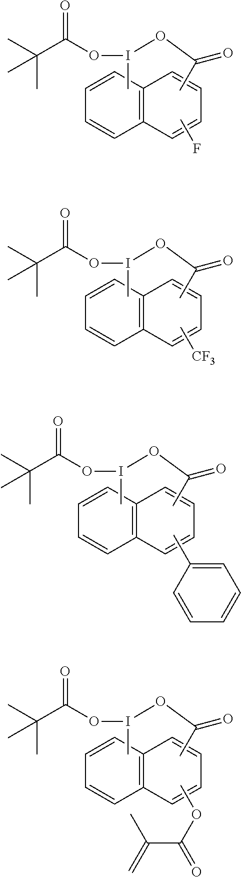

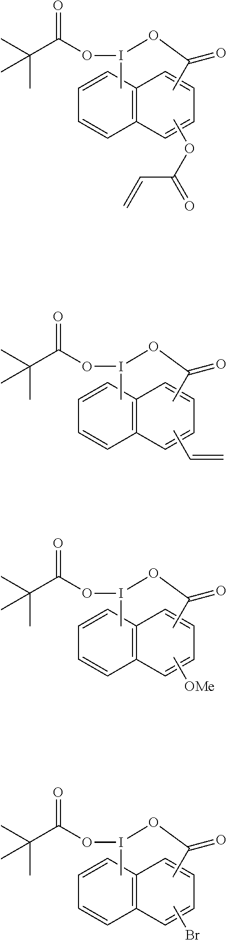

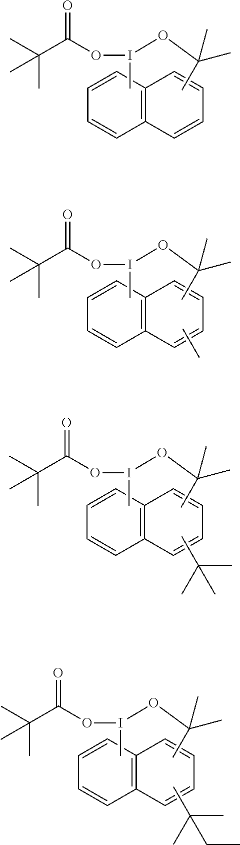

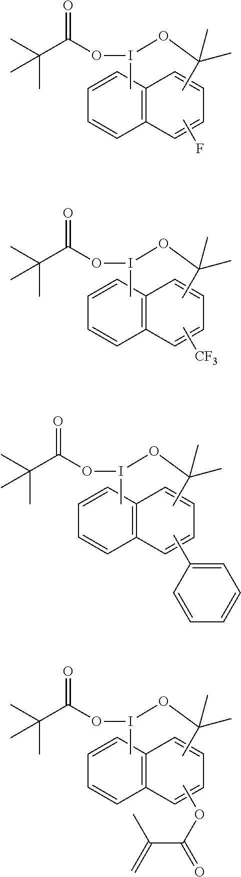

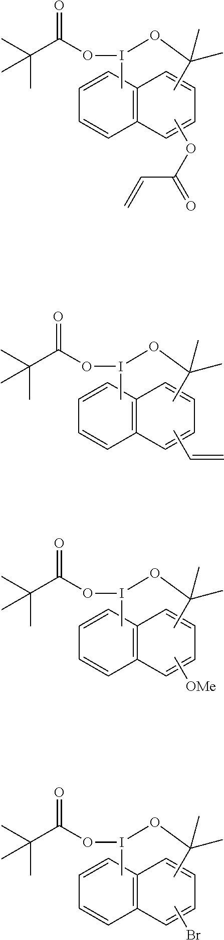

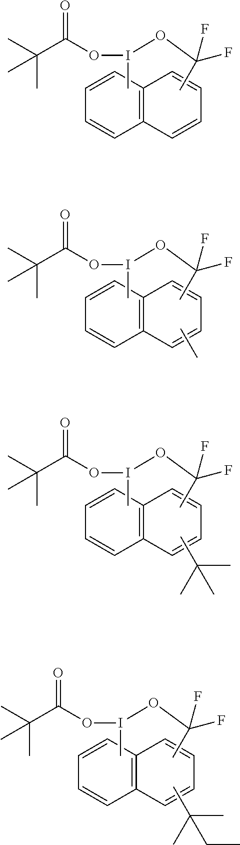

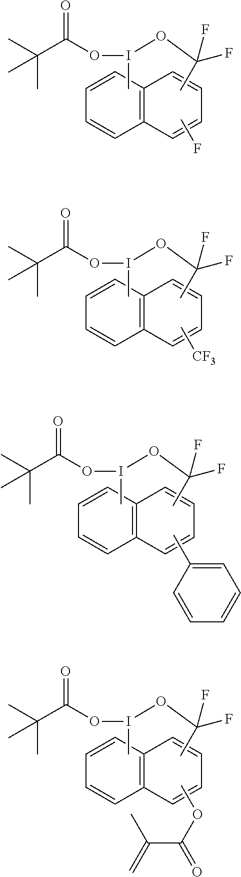

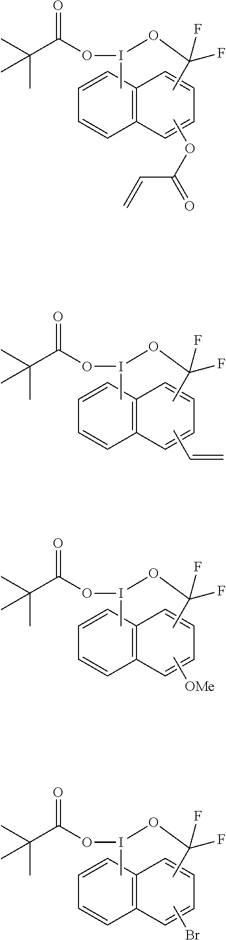

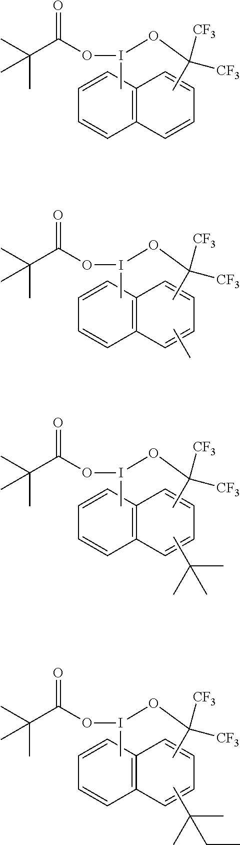

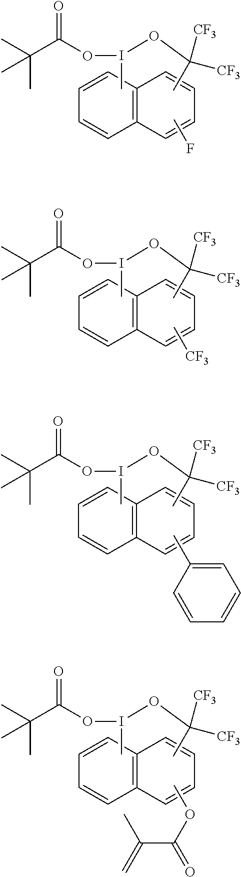

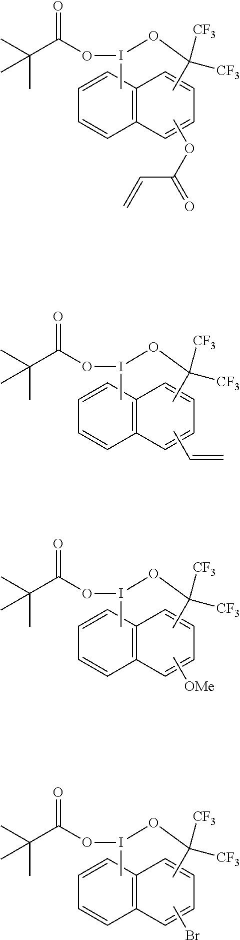

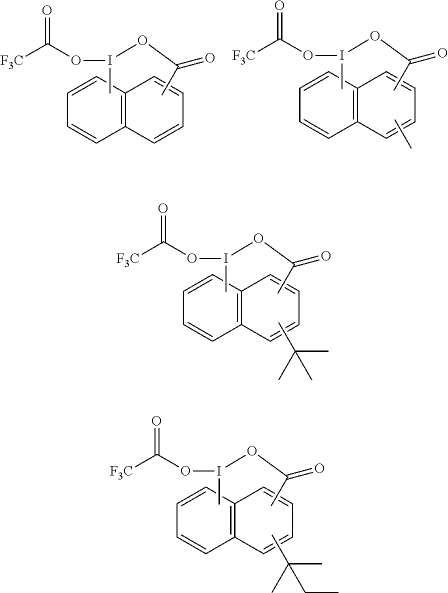

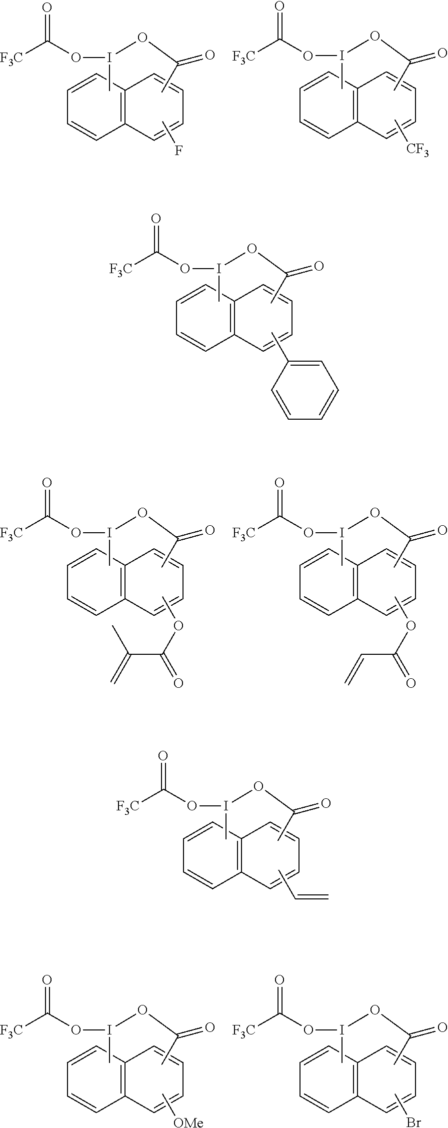

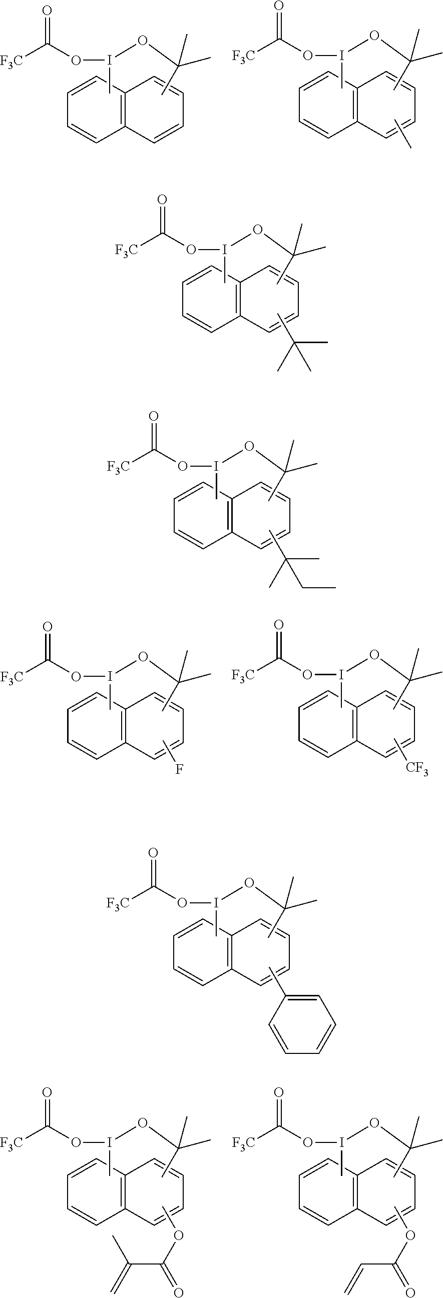

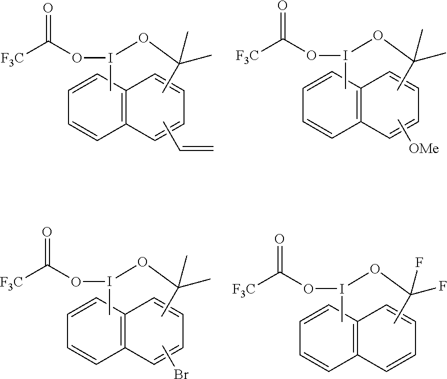

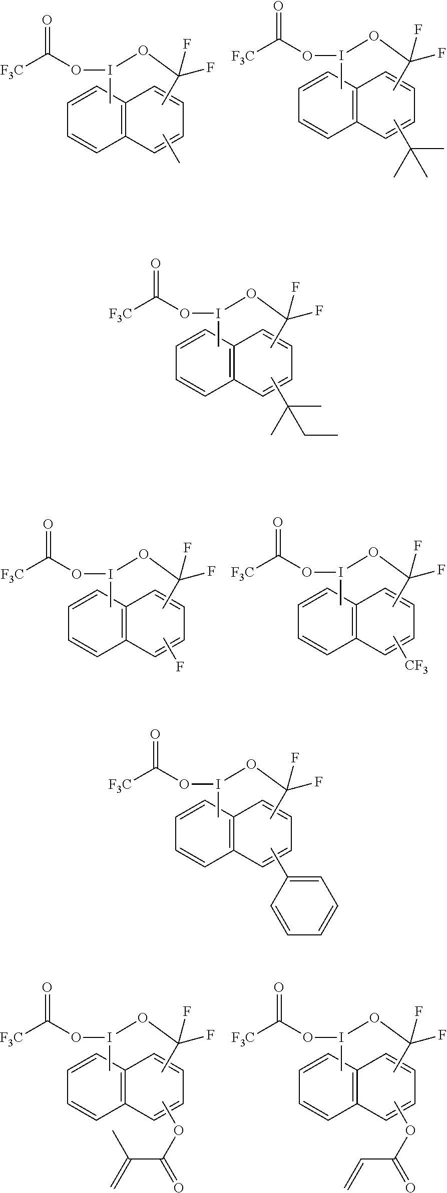

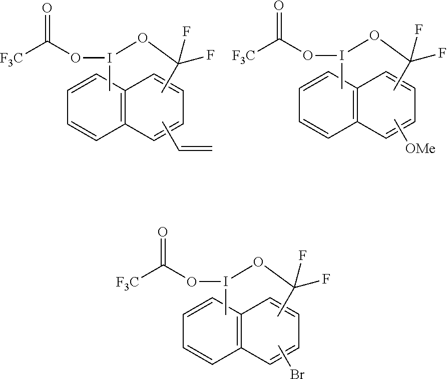

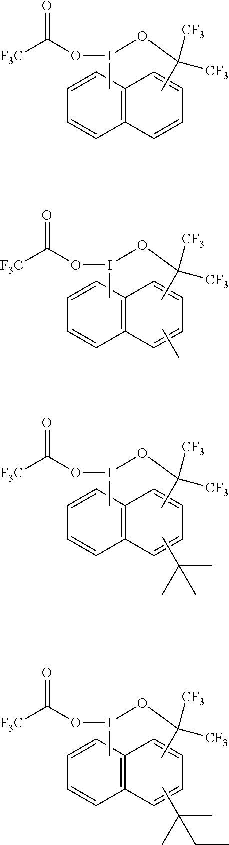

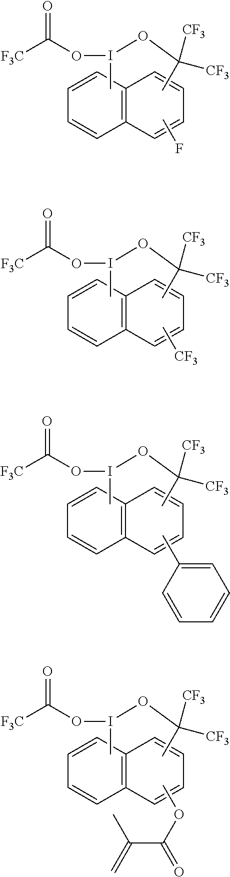

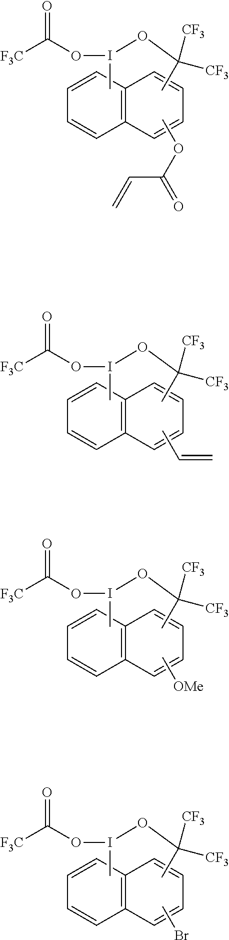

Examples of the hypervalent iodine compound having formula (2) are shown below, but not limited thereto.

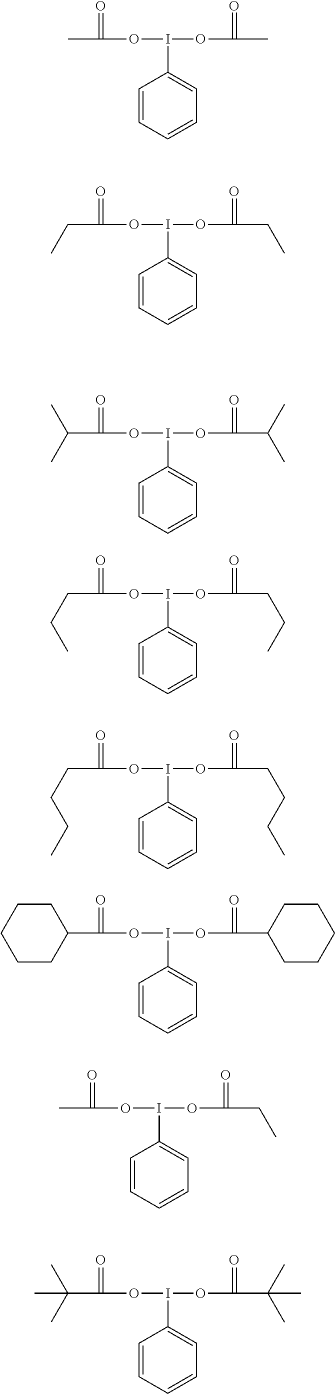

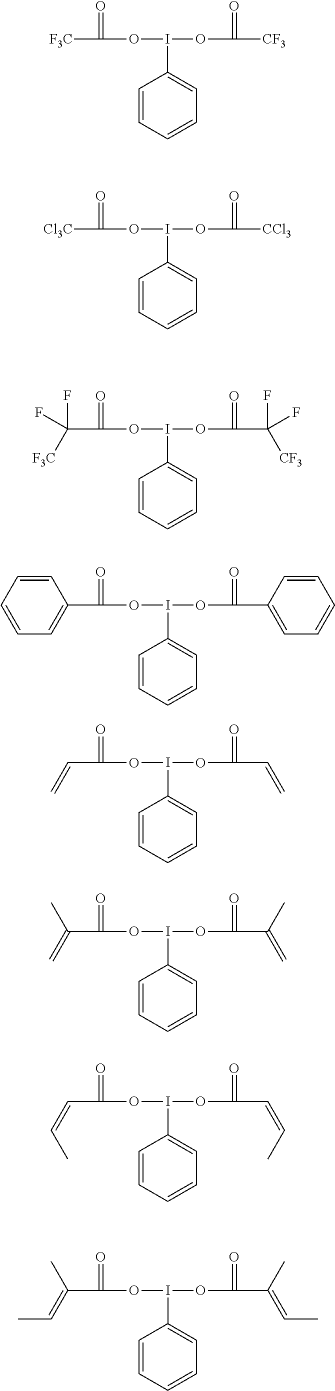

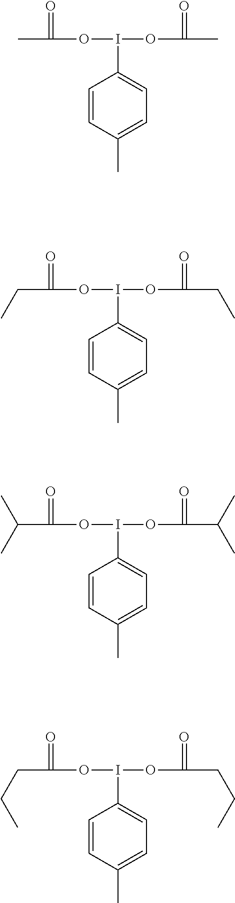

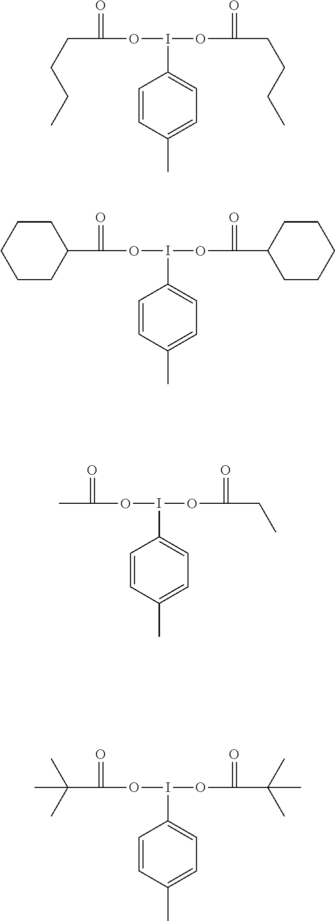

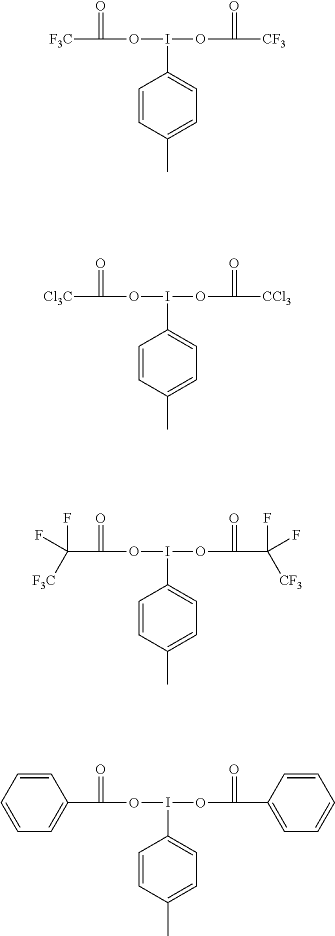

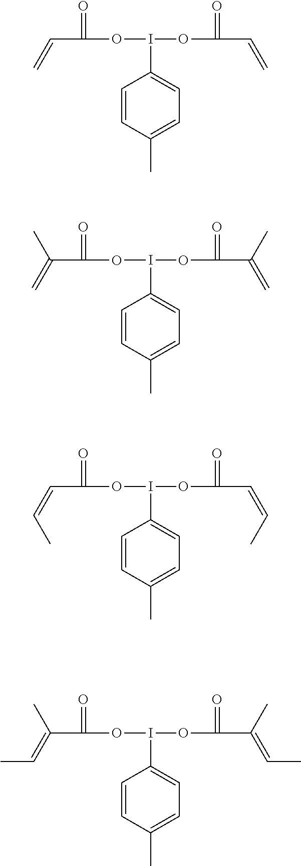

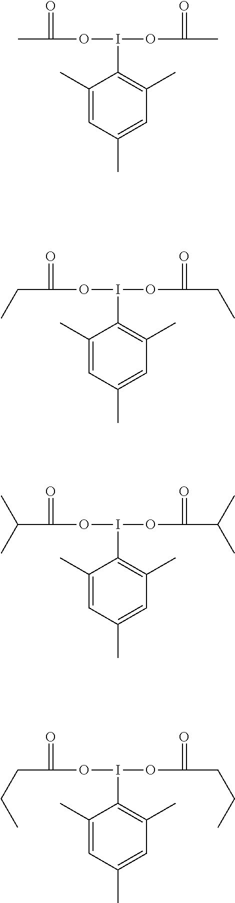

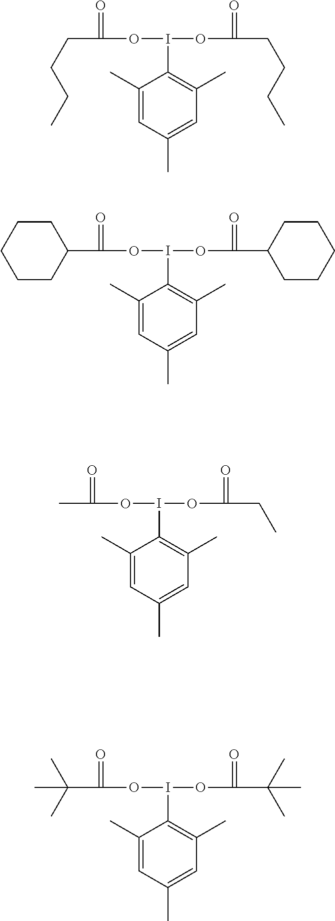

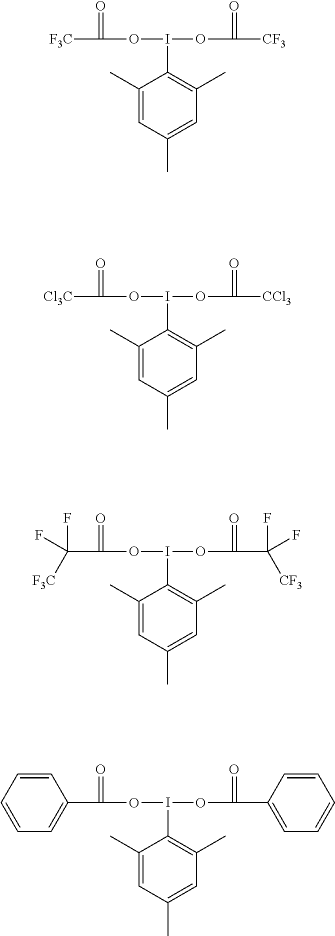

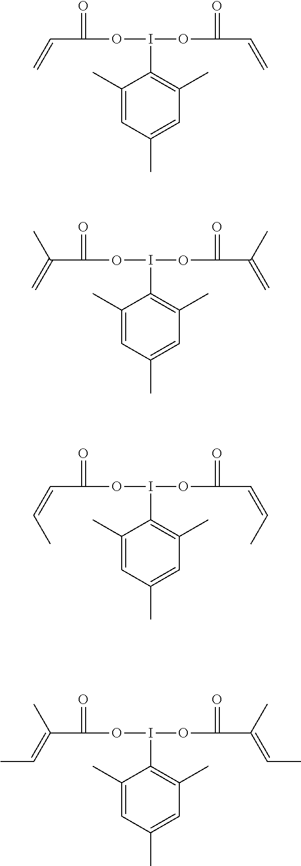

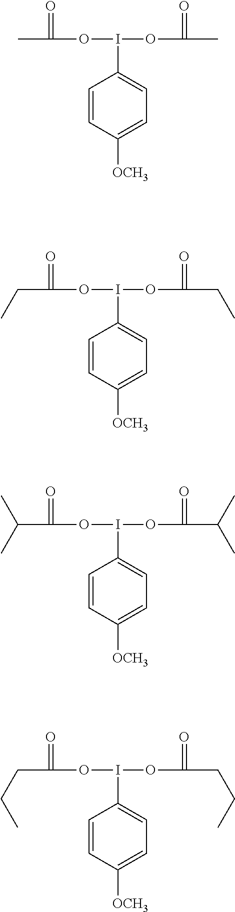

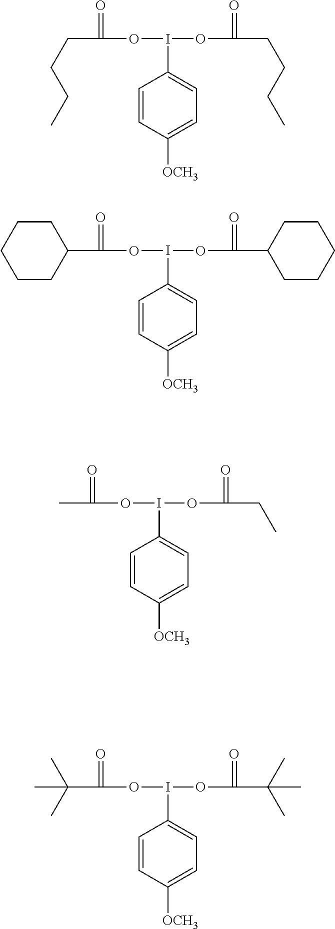

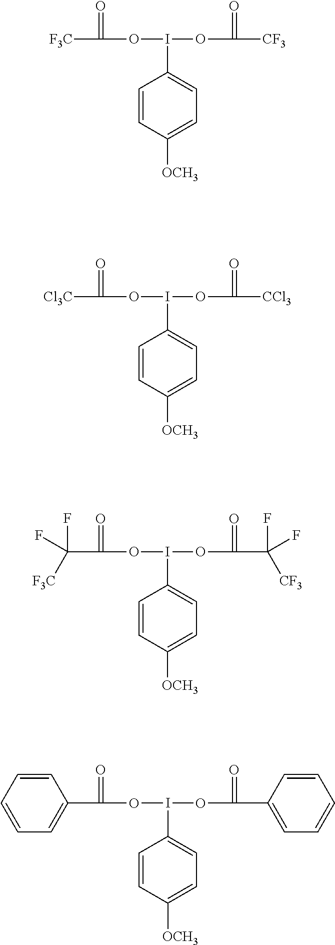

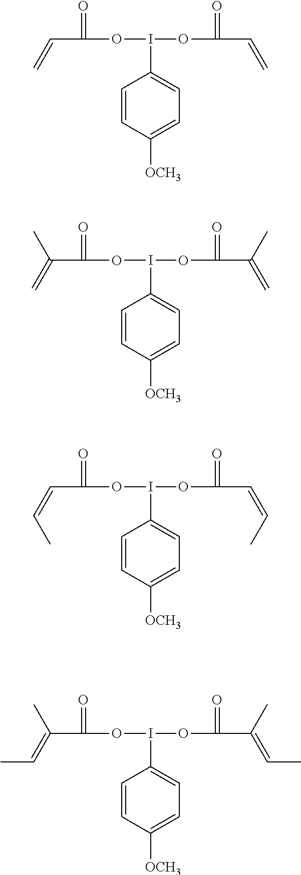

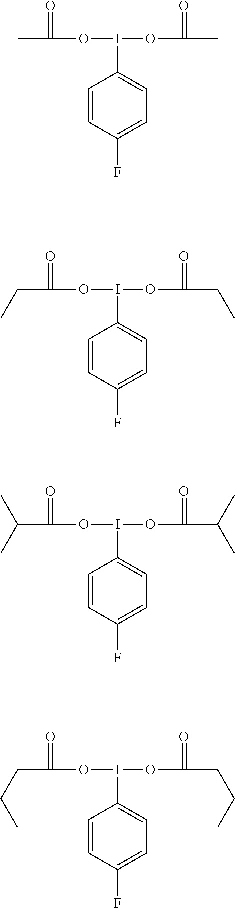

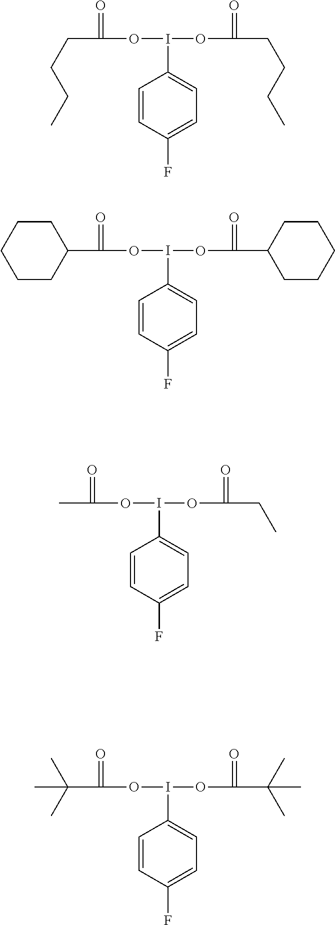

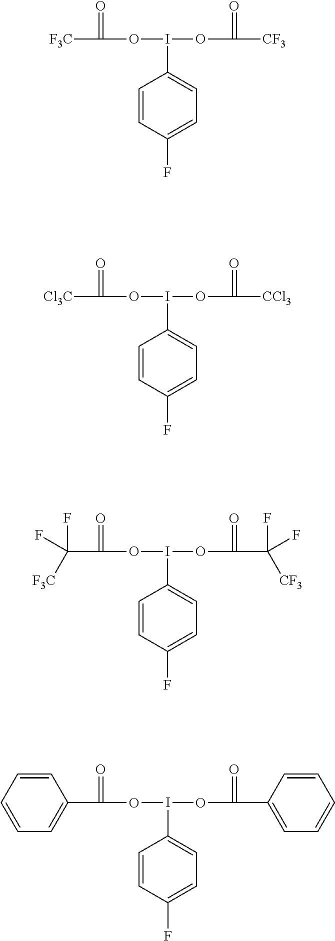

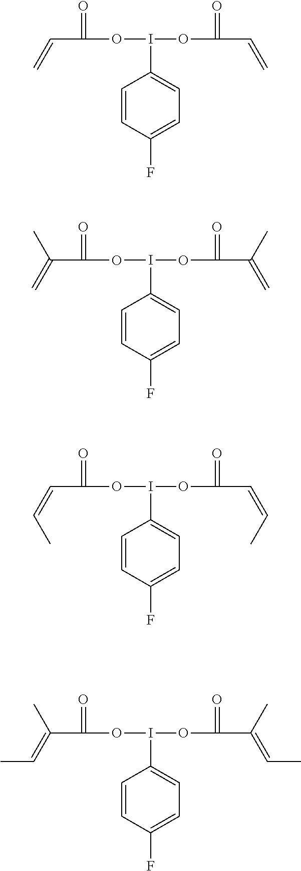

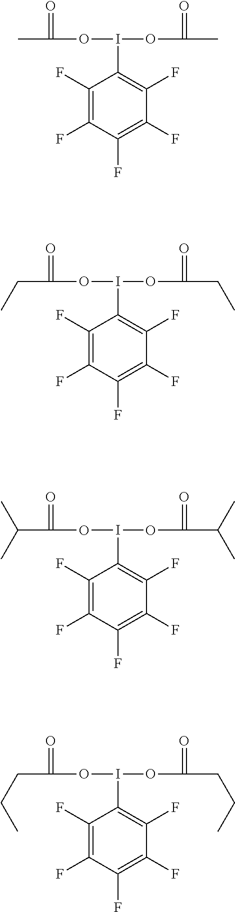

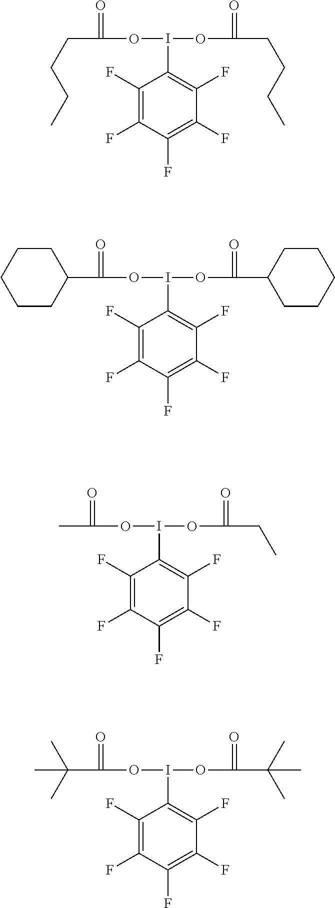

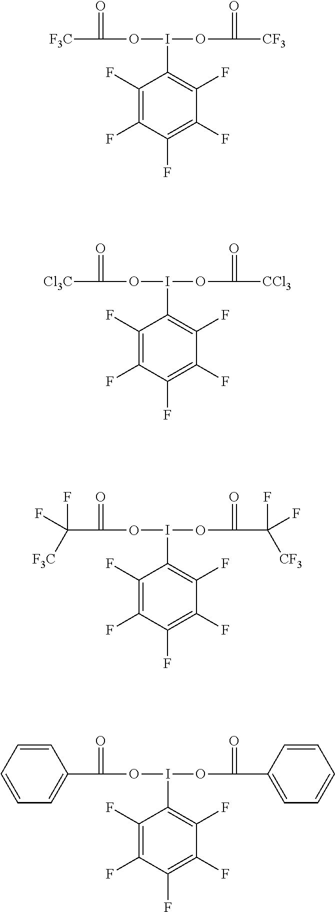

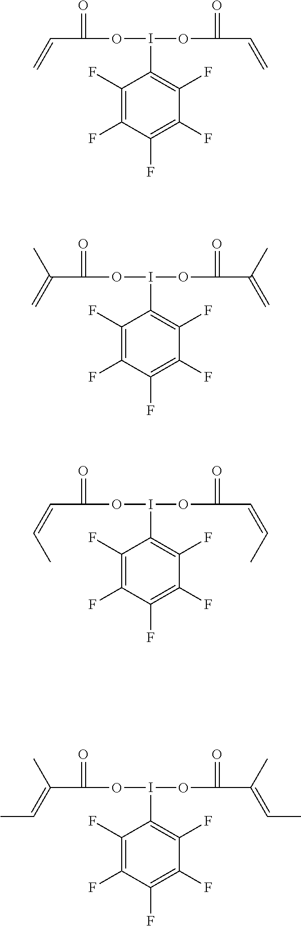

### [Carboxylic Acid]

The carboxylic acid may be any of compounds generally defined as carboxylic acids in the organic chemistry, preferably a carboxylic acid having the formula (3).

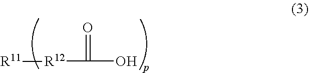

In formula (3), p is an integer of 1 to 4. R¹¹ is a C₁-C₄₀ p-valent hydrocarbon group or C₂-C₄₀ p-valent heterocyclic group, R¹¹ may also be an ether bond, carbonyl group, azo group, thioether bond, carbonate bond, carbamate bond, sulfinyl group or sulfonyl group when p=2. Some or all of the hydrogen atoms in the p-valent hydrocarbon group or p-valent heterocyclic group may be substituted by a heteroatom-containing moiety, and some —CH₂— in the p-valent hydrocarbon group may be replaced by a heteroatom-containing moiety. R¹² is a single bond or C₁-C₂₀ hydrocarbylene group, some or all of the hydrogen atoms in the hydrocarbylene group may be substituted by a heteroatom-containing moiety, and some —CH₂— in the hydrocarbylene group may be replaced by a heteroatom-containing moiety. A plurality of R¹² may be identical or different when p=2, 3 or 4.

The p-valent hydrocarbon group R¹¹ may be saturated or unsaturated and straight, branched or cyclic. The p-valent hydrocarbon group is obtained by eliminating p number of hydrogen from a hydrocarbon. Examples of the hydrocarbon include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Exemplary of the C₁-C₄₀ alkanes are methane, ethane, propane, butane, pentane, hexane, heptane, octane, nonane, decane, and structural isomers thereof. Exemplary of the C₂-C₄₀ alkenes are ethylene, propylene, butene, pentene, hexene, heptene, octene, nonene, decene, and structural isomers thereof. Exemplary of the C₂-C₄₀ alkynes are acetylene, propyne, butyne, pentyne, hexyne, heptyne, octyne, nonyne, decyne, and structural isomers thereof. Exemplary of the C₃-C₄₀ cyclic saturated hydrocarbons are cyclopropane, cyclobutane, cyclohexane, cycloheptane, cyclooctane, adamantane, and norbornane. Exemplary of the C₃-C₄₀ cyclic unsaturated hydrocarbons are cyclopropene, cyclobutene, cyclopentene, cyclohexene, cycloheptene, cyclooctene, and norbornene. Exemplary of the C₆-C₄₀ aromatic hydrocarbons are benzene, naphthalene, and biphenyl.

The p-valent heterocyclic group R¹¹ are obtained by eliminating p number of hydrogen from a heterocyclic compound. Suitable heterocyclic compounds include furans, pyridines, pyrazoles, and thiazolidines.

Some or all of the hydrogen atoms in the p-valent hydrocarbon group or p-valent heterocyclic group may be substituted by a moiety containing a heteroatom such as oxygen, sulfur, nitrogen or halogen, so that the group may contain a hydroxy, cyano, fluorine, chlorine, bromine or iodine. Also, some —CH₂— in the p-valent hydrocarbon group may be replaced by a moiety containing a heteroatom such as oxygen, sulfur or nitrogen, so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

The hydrocarbylene group R¹² may be saturated or unsaturated and straight, branched or cyclic. Examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl and dodecane-1,12-diyl; C₃-C₂₀ cyclic saturated hydrocarbylene groups such as cyclopentanediyl, cyclohexanediyl, norbornanediyl, and adamantanediyl; C₂-C₂₀ unsaturated aliphatic hydrocarbylene groups such as vinylene and propene-1,3-diyl; C₆-C₂₀ arylene groups such as phenylene and naphthylene; and combinations thereof. In the hydrocarbylene group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, thioether bond, ester bond, sulfonate ester bond, carbonate bond, carbamate bond, lactone ring, sultone ring, or carboxylic anhydride (—C(═O)—O—C(═O)—).

Of the carboxylic acids having formula (3), those wherein p is 2, 3 or 4 are preferred. When mixed with the hypervalent iodine compound, such a carboxylic acid is likely to form a robust resist film having a high molecular weight, which is preferred from the aspects of etch resistance and developer resistance.

Examples of the carboxylic acid are shown below.

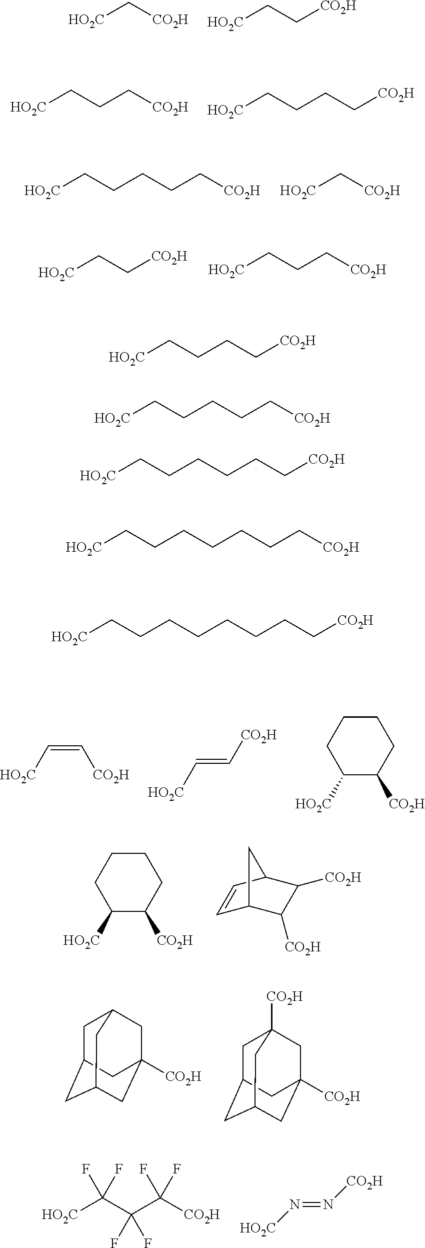

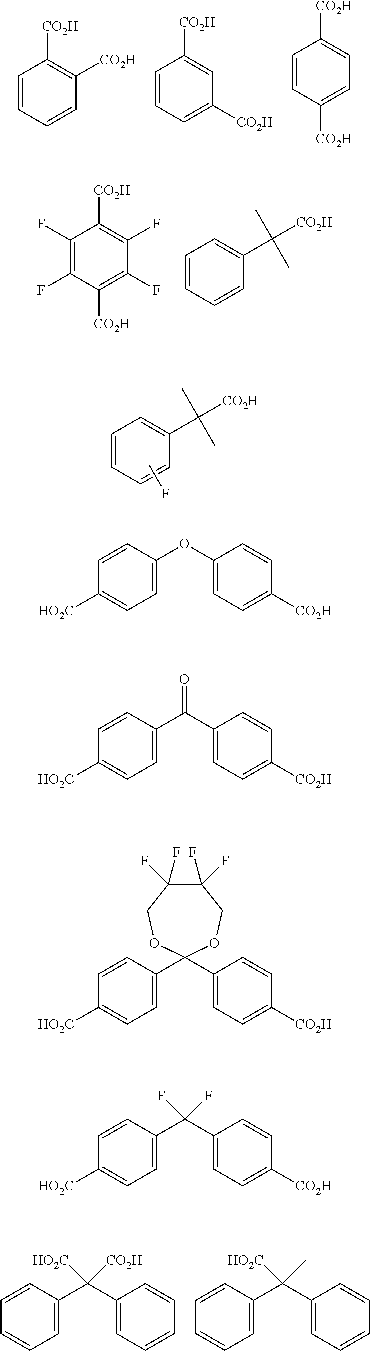

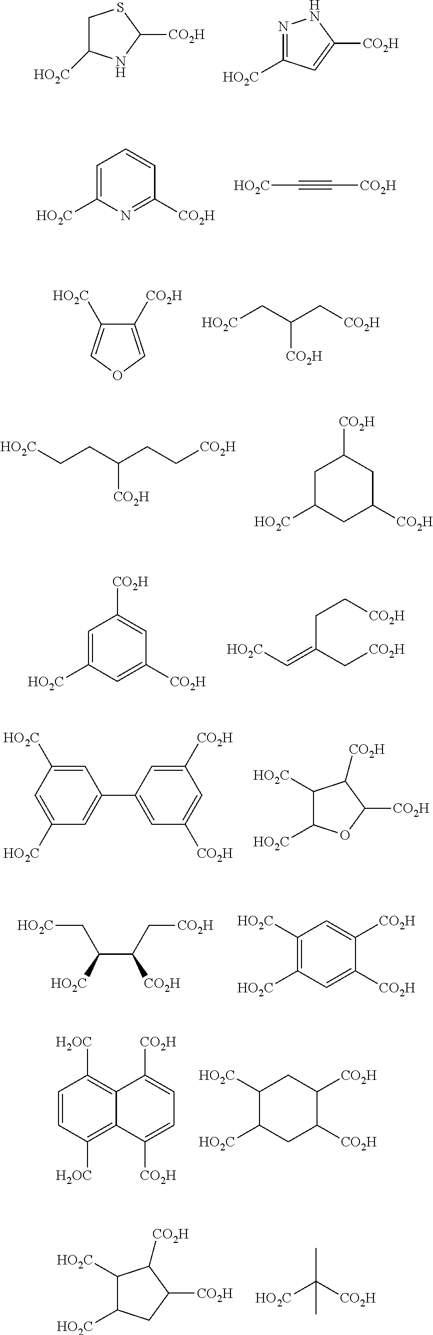

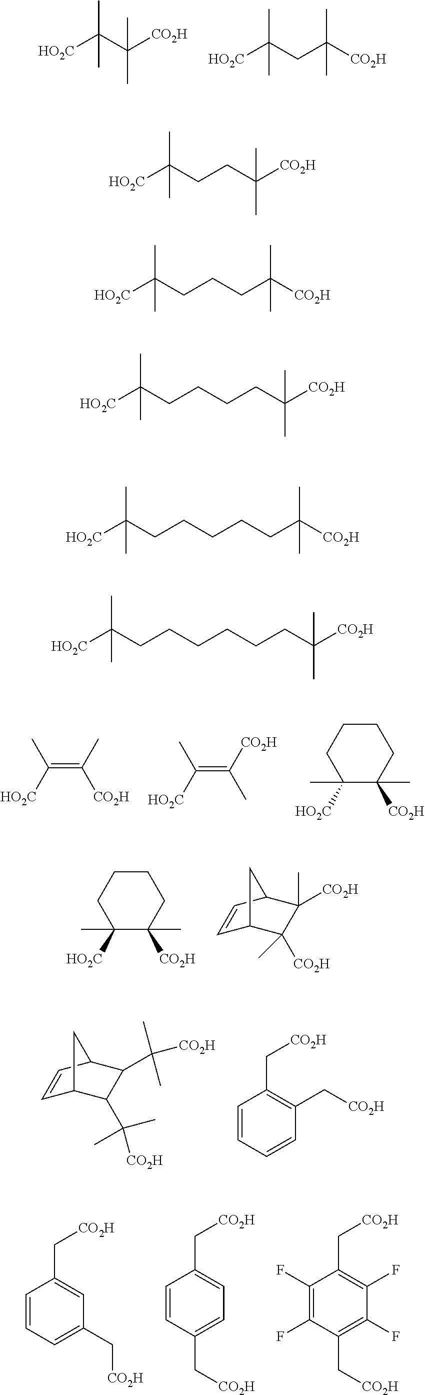

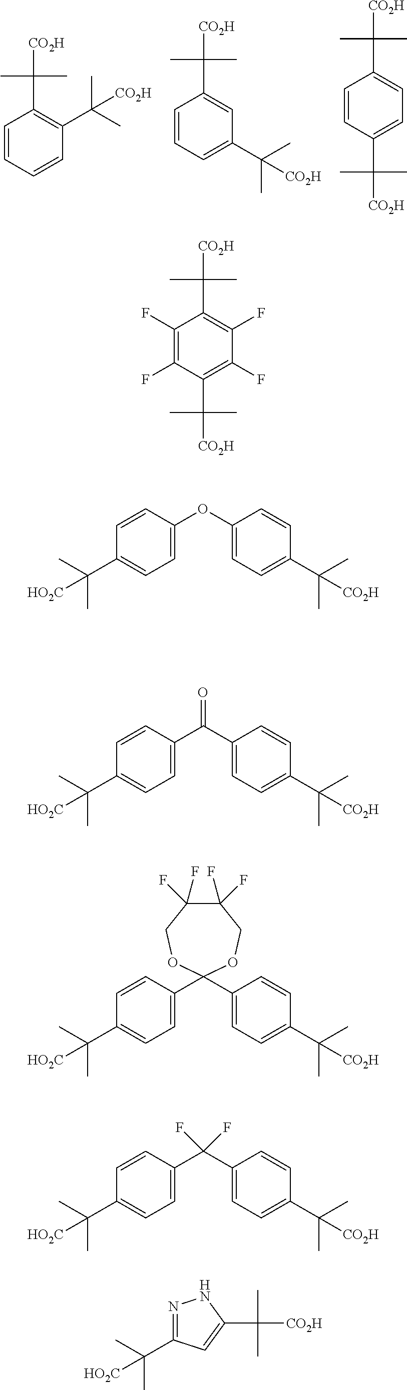

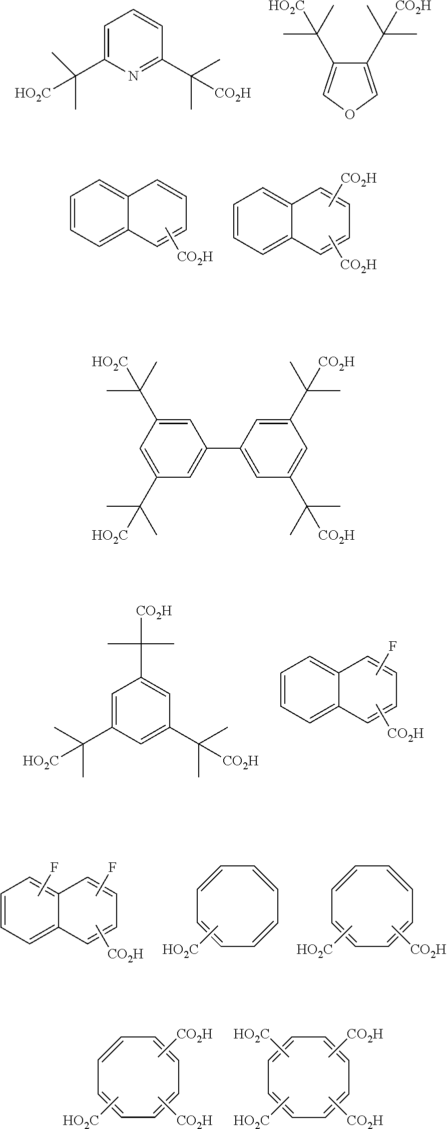

In the resist composition, the hypervalent iodine compound and the carboxylic acid are preferably present such that the molar ratio of the hypervalent iodine compound to the carboxylic acid may range from 10:90 to 90:10, more preferably from 20:80 to 80:20, even more preferably from 30:70 to 70:30. The hypervalent iodine compound may be used alone or as a mixture of two or more. The carboxylic acid may be used alone or as a mixture of two or more.

### [Organic Solvent]

The resist composition further contains a solvent. The solvent is not particularly limited as long as the hypervalent iodine compound, the carboxylic acid and other components are dissolvable therein and a film can be formed from the resulting solution. Organic solvents are preferred. Suitable organic solvents include ketones such as cyclohexanone, methyl 2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, and 4-methyl-2-pentanol; ethers such as propylene glycol monomethyl ether, ethylene glycol monomethyl ether, propylene glycol monoethyl ether, ethylene glycol monomethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, and methyl 2-hydroxyisobutyrate; carboxylic acids such as formic acid, acetic acid, and propionic acid; lactones such as γ-butyrolactone, and mixtures thereof.

The solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent. The solvent may be used alone or in admixture of two or more.

### [Other Components]

The resist composition may further contain a surfactant as another component. The surfactant is preferably selected from fluorochemical and silicon-based surfactants. Exemplary surfactants are described, for example, in US 2008/0248425, paragraph [0276]. Also useful are surfactants other than the fluorochemical and silicon-based surfactants, as described, for example, in US 2008/0248425, paragraph [0280]. When used, the surfactant is preferably present in an amount of 0.0001 to 2% by weight based on the overall solids. The surfactant may be used alone or in admixture.

The resist composition may further contain a radical scavenger (or radical trapping agent) as an additional component. When added, the radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol. When used, the radical scavenger is preferably present in an amount of 0.01 to 10% by weight based on the overall solids. The radical scavenger may be used alone or in admixture.

The resist composition may contain a crosslinker. The crosslinker serves to promote crosslinking reaction in the photolithography to eventually reduce an etching rate.

Suitable crosslinkers are compounds having an unsaturated carbon-carbon bond such as vinyl, (meth)acrylate, allyl, alkynyl or aromatic ring as a functional group. Suitable compounds having a vinyl group include linear alkenes, branched alkenes, and cyclic alkenes, which may have a substituent. Suitable compounds having a (meth)acryloyl group include acrylic acids, methacrylic acids, acrylates, and methacrylates, which may have a substituent. Suitable compounds having an allyl group include allyl alcohols, allyl ethers, allyl esters, allyl amides, allyl amines, and allyl-containing isocyanurates, which may have a substituent. Suitable compounds having an alkynyl group include straight alkynes, branched alkynes, cyclic alkynes, alkynyl alcohols, alkynyl ethers, alkynyl esters, alkynyl amides, alkynyl amines, alkynyl-containing isocyanurates, which may have a substituent. Suitable compounds having an aromatic ring include arenes, heteroarenes, styrenes, stilbenes, phenylacethylenes, acenaphthylenes, and chalcones, which may have a substituent. The crosslinker may have one or more of the foregoing functional groups. The number of functional groups in the crosslinker is preferably from 1 to 10, more preferably from 2 to 8.

When the resist composition contains the crosslinker, the amount of the crosslinker is preferably 0.01 to 50% by weight of the overall solids. The crosslinker may be used alone or in admixture.

When the resist composition contains the crosslinker, it may further contain a photopolymerization initiator. Upon receipt of high-energy radiation, the photopolymerization initiator generates radicals to promote crosslinking of the crosslinker.

Examples of the photopolymerization initiator include benzophenone derivatives such as benzophenone, methyl O-benzoylbenzoate, 4-benzyol-4′-methyl diphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)benzyl]phenyl}-2-methylpropan-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyl dimethyl ketal, and benzyl-β-methoxyethylacetal; benzoin derivatives such as benzoin, benzoin methyl ether, and 2-hydroxy-2-methyl-1-phenylpropan-1-one; oxime compounds such as 1-phenyl-1,2-butanedione-2-(O-methoxycarbonyl) oxime, 1-phenyl-1,2-propanedione-2-(O-methoxycarbonyl) oxime, 1-phenyl-1,2-propanedione-2-(O-ethoxycarbonyl) oxime, 1-phenyl-1,2-propanedione-2-(O-benzoyl) oxime, 1,3-diphenylpropanetrione-2-(O-ethoxycarbonyl) oxime, 1-phenyl-3-ethoxypropanetrione-2-(O-benzoyl) oxime 1,2-octanedione, 1-{4-(phenylthio)-2-(O-benzoyl) oxime ethanone, and 1-[9-ethyl-6-(2-methylbenzoyl)-9H-carbazol-3-yl]-1-(O-acetyloxime); «-hydroxyketone compounds such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)benzyl]phenyl}-2-methylpropane; α-aminoalkylphenone compounds such as 2-benzyl-2-dimethylamino-1-(4-morpholinophenyl) butanone-1 and 2-dimethylamino-2-(4-methylbenzyl)-1-(4-morpholin-4-ylphenyl) butan-1-one; phosphine oxide compounds such as bis(2,4,6-trimethylbenzoyl)phenylphosphine oxide, bis(2,6-dimethoxybenzoyl)-2,4,4-trimethylpentylphosphine oxide, and 2,4,6-trimethylbenzoyl diphenylphosphine oxide; and titanocene compounds such as bis(η5-2,4-cyclopentadien-1-yl)-bis(2,6-difluoro-3-(1H-pyrrol-1-yl)phenyl)titanium.

When the resist composition contains the photopolymerization initiator, the amount of the initiator is preferably 0.1 to 10% by weight, more preferably 0.1 to 5% by weight, even more preferably 0.1 to 1% by weight of the overall solids. A sufficient effect is available as long as the amount is 0.1% by weight or more.

The resist composition contains the hypervalent iodine compound and the carboxylic acid as main components, but not a polymer containing an acid labile group and a photoacid generator as used in conventional chemically amplified resist compositions. Nevertheless, this resist composition works such that the region thereof exposed to EB or EUV is removed by dry process development to form a positive tone pattern, or the unexposed region thereof is removed by dry process development to form a negative tone pattern. Although its mechanism is not well understood, the following mechanism is presumed.

The hypervalent iodine compound is a three-coordinate compound having carboxylate ligands as represented by formula (1) or (2). When such a three-coordinate iodine compound is mixed with a carboxylic acid, replacement of carboxylate ligands takes place as equilibration reaction. If the original carboxylate ligands are removed by any suitable means, a hypervalent iodine compound having new ligands is created. For example, if iodobenzene diacetate which is relatively readily available as the hypervalent iodine compound is mixed with a carboxylic acid having a high molecular weight, and the resulting low-boiling acetic acid is removed, then ligand exchange is completed. If the ligand has a fully high molecular weight, then a robust resist film is formed. Particularly when the carboxylic acid has a plurality of carboxy groups, for example, a dicarboxylic acid is used, a high molecular weight compound of polyester structure having the hypervalent iodine compound is formed. This ensures film formability.

The combined form of hypervalent iodine compound and carboxylic acid is formed during film preparation. That is, by removing a low-molecular-weight carboxylic acid formed during film formation and subsequent bake step, ligand exchange reaction is completed and a resist film is formed.

The resist composition may become of either positive or negative tone depending on a choice of components. The resist film obtained from the positive resist composition contains the polymer to which the hypervalent iodine compound is bonded during film formation. However, upon receipt of light, the hypervalent iodine compound is decomposed into a monovalent iodine compound. At the same time, the crosslink between the hypervalent iodine compound and the carboxylic acid is canceled and the molecular weight is reduced. As a result, a difference in etching rate is established between the exposed and unexposed regions. Through the dry process development, a pattern of positive tone wherein the film in the unexposed region is left is formed.

In contrast, the resist film obtained from the negative resist composition contains the polymer crosslinked with the hypervalent iodine compound, which is formed during film formation. Upon receipt of light, the hypervalent iodine compound is decomposed (whereby the crosslink or bond is changed) and converted into a chemical species having a lower etching rate than the unexposed region. As a result, a difference in etching rate is established between the exposed and unexposed regions. Through the dry process development, a pattern of negative tone wherein the film in the exposed region is left is formed.

It is unknown what component should be selected in order that the resist composition become of positive or negative tone. When the resist film obtained from the resist composition is of positive tone, the exposed region becomes soluble in an organic solvent. When the resist film obtained from the resist composition is of negative tone, the exposed region becomes insoluble in an alkaline aqueous solution. This gives the criterion of judgment.

From the foregoing presumption, the inventive resist composition is regarded as falling in the concept of non-chemically-amplified resist composition. There is no need for an acid labile group-containing polymer and a photoacid generator as used in conventional chemically amplified resist compositions. Using the inventive resist composition, a small size pattern can be resolved without any adverse effect (e.g., image blur) due to acid diffusion.

The inventive resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, the inventive resist composition which does not use metal elements is advantageous in defectiveness over the metal resist and eliminates the problem of solvent solubility. The inventive resist composition has a wide range of application because it becomes of both positive and negative tones. In the step of forming contact holes, for example, although a metal resist composition subject to negative tone development requires the reversal processing step after pillar pattern formation, the positive resist composition does not require the reversal step. From the aspect of process simplicity, the inventive resist composition is regarded more useful than the metal resist composition.

JP-A 2015-180928 and JP-A 2018-095853 describe a resist composition comprising a hypervalent iodine compound as an additive and a resist composition comprising a base polymer having a hypervalent iodine compound incorporated in its framework. It is described in these patent documents that these resist compositions are successful only in improving line edge roughness. They refer nowhere to a possibility of photo-decomposition of the hypervalent iodine compound and an ability to function as a non-chemically amplified resist. In these resist compositions, the hypervalent iodine compound is not a main component. It is then believed that a material capable of reducing shot noise during the EUV lithography and forming a small size pattern as the non-chemically amplified resist is not conceivable from these patent documents. That is, the present invention provides a definitely novel resist composition and pattern forming process.

### [Resist Pattern Forming Process]

One embodiment of the invention is a resist pattern forming process comprising the steps of:
(i) applying a resist composition as defined above onto a substrate or a substrate having an underlying film deposited thereon to form a resist film on the substrate or the underlying film,
(ii) exposing the resist film to high-energy radiation,
(iii) baking the exposed resist film, and
(iv) dry etching the baked resist film for development to form a resist pattern.
   [Step (i)]

Step (i) is to apply the resist composition onto a substrate or a substrate having an underlying film thereon to form a resist film on the substrate or underlying film. Specifically, the resist composition is applied onto a substrate for integrated circuit fabrication (e.g., Si, SiO₂, SiN, SiON, TiN, WSi, BPSG, SOG, or organic antireflective coating) or a substrate having an underlying film thereon, or a substrate for mask circuit fabrication (e.g., Cr, CrO, CrON, MoSi₂, or SiO₂) or a substrate having an underlying film thereon by any suitable technique such as spin coating, roll coating, flow coating, dip coating, spray coating or doctor coating. The coating is prebaked (PAB) on a hot plate at a temperature of preferably 60 to 200° C. for 10 seconds to 30 minutes, more preferably at 80 to 160° C. for 30 seconds to 20 minutes to form a resist film having a thickness of 0.01 to 2 μm. Notably, the underlying film refers to a film formed between a substrate and a resist film in the multilayer resist process. The underlying film is not particularly limited and any of well-known films may be used.

[Step (ii)]

Step (ii) is to expose the resist film to high-energy radiation. The radiation is selected from among UV, deep UV, EB at accelerating voltage 1 to 150 kV, EUV of wavelength 3 to 15 nm, X-ray, soft X-ray, excimer laser radiation, γ-ray, and synchrotron radiation. On use of UV, deep UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 5,000 μC/cm², more preferably about 0.5 to 3,000 μC/cm². The resist composition is best suited in micropatterning using EB or EUV as the high-energy radiation.

[Step (iii)]

Step (iii) is to bake (or heat treat) the exposed resist film. This step is also referred to as post-exposure bake (PEB). PEB may be performed on a hot plate or by IR irradiation, laser irradiation, or hot air blowing. PEB may also be performed by inserting the wafer into an atmosphere at the baking temperature. Most of the currently used heating means use a hot plate. Once the substrate on which a resist film is formed is rested on a hot plate, the resist film is heated by heat conduction through the substrate. By temperature control of the hot plate, the temperature at which the resist film is heated is adjustable.

The PEB temperature is preferably 30 to 170° C., more preferably 40 to 160° C., even more preferably 50 to 150° C. The PEB time is preferably 10 seconds to 30 minutes, more preferably 10 seconds to 20 minutes.

Flood exposure of the resist film after the PEB may be included. During flood exposure, crosslinking takes place in the resist film whereby the resist film has higher etching resistance. For the flood exposure, high-energy radiation, especially UV, deep UV, X-ray and soft X-ray may be used.

[Step (iv)]

Step (iv) is to dry etch the baked resist film for development to form a resist pattern. On use of a positive resist composition, the exposed region is scraped off to open the space region. On use of a negative resist composition, the unexposed region is scraped off to open the space region.

Dry etching may be carried out in a conventional dry etching system. Reactive ion etching (RIE) is performed in the chamber with a dry etching gas-containing plasma. As the dry etching gas, use may be made of gas mixtures of oxygen, hydrogen, ammonia, fluorocarbon, chlorine or bromine diluted with nitrogen, argon, helium, carbon dioxide, carbon monoxide, or sulfur dioxide. Gas mixtures containing at least one of oxygen and tetrafluoromethane are preferably used. It is preferred from the aspect of easy control of an etching rate to use a mixture of oxygen and nitrogen or a mixture of tetrafluoromethane and nitrogen.

Suitable dry etching conditions are described below. On use of a gas mixture of oxygen and nitrogen, for example, the pressure in the chamber is preferably 0.01 to 100 Pa, more preferably 0.1 to 30 Pa. The radio frequency (RF) power is preferably 50 to 1,500 W, more preferably 150 to 1,000 W. The bias power is preferably 0 to 300 W, more preferably 30 to 200 W. The flow rate of oxygen gas is preferably 3 to 300 sccm, more preferably 5 to 150 sccm. The flow rate of nitrogen gas is preferably 5 to 600 sccm, more preferably 10 to 500 sccm. The treating temperature during development is preferably −20° C. to 30° C., more preferably −10° C. to 30° C.

On use of a gas mixture of tetrafluoromethane and nitrogen, the chamber pressure is preferably 0.01 to 100 Pa, more preferably 0.1 to 30 Pa. The RF power is preferably 50 to 1,500 W, more preferably 150 to 1,000 W. The bias power is preferably 0 to 300 W, more preferably 30 to 200 W. The flow rate of tetrafluoromethane gas is preferably 3 to 300 sccm, more preferably 5 to 150 sccm. The flow rate of nitrogen gas is preferably 5 to 500 sccm, more preferably 10 to 300 sccm. The treating temperature during development is preferably −20° C. to 30° C., more preferably −10° C. to 30° C.

The dry etching time may be set as appropriate, preferably in the range of 30 to 300 seconds, more preferably 30 to 120 seconds.

A hole or trench pattern after development may be shrunk by the thermal flow, RELACS® or DSA process.

### EXAMPLES

Examples of the invention are given below by way of illustration and not by way of limitation. The abbreviation “pbw” is parts by weight.

### [1] Preparation of Resist Composition

### Examples 1-1 to 1-10 and Comparative Examples 1-1 to 1-3

Resist compositions (R-01 to R-10) were prepared by dissolving a hypervalent iodine compound and a carboxylic acid in a solvent in accordance with the recipe shown in Table 1, and filtering the solution through a Teflon® filter having a pore size of 0.2 μm. Also, resist compositions (CR-01 to CR-03) were prepared by dissolving a base polymer, a photoacid generator, and a sensitivity modifier in a solvent containing 0.01 wt % of a surfactant (PF-636, Omnova Solutions, Inc.) in accordance with the recipe shown in Table 2, and filtering the solution through a Teflon® filter having a pore size of 0.2 μm.

TABLE 1

| | | | Hypervalent | Hypervalent | | | |
|---|---|---|---|---|---|---|---|
| | | | iodine | iodine | Carboxylic | | |
| | | Resist | compound 1 | compound 2 | acid | Solvent 1 | Solvent 2 |
| | | composition | (pbw) | (pbw) | (pbw) | (pbw) | (pbw) |
| Example | 1-1 | R-01 | I-1-1 (10) | — | CA-1 (7.3) | PGMEA (800) | AcOH (200) |
| | 1-2 | R-02 | I-1-2 (10) | — | CA-1 (7.3) | PGMEA (800) | AcOH (200) |
| | 1-3 | R-03 | I-1-3 (14) | — | CA-1 (7.3) | PGMEA (800) | AcOH (200) |
| | 1-4 | R-04 | — | I-2-1 (10) | CA-2 (3.5) | PGMEA (800) | AcOH (200) |
| | 1-5 | R-05 | — | I-2-1 (10) | CA-3 (7.2) | PGMEA (800) | AcOH (200) |
| | 1-6 | R-06 | — | I-2-1 (10) | CA-4 (50) | PGMEA (800) | AcOH (200) |
| | 1-7 | R-07 | — | I-2-1 (10) | CA-5 (6.5) | PGMEA (800) | AcOH (200) |
| | 1-8 | R-08 | — | I-2-1 (10) | CA-6 (9.9) | PGMEA (800) | AcOH (200) |
| | 1-9 | R-09 | I-1-1 (10) | — | CA-7 (7.6) | PGMEA (800) | AcOH (200) |
| | 1-10 | R-10 | I-1-1 (10) | — | CA-8 (5.9) | PGMEA (800) | AcOH (200) |

TABLE 2

| | | | | Photoacid | Sensitivity | | |
|---|---|---|---|---|---|---|---|
| | | Resist | Polymer | generator | modifier | Solvent 1 | Solvent 2 |
| | | composition | (pbw) | (pbw) | (pbw) | (pbw) | (pbw) |
| Comparative | 1-1 | CR-01 | P-1 (80) | PAG-1 (19) | Q-1 (6) | PGMEA (1890) | GBL (210) |
| Example | 1-2 | CR-02 | P-1 (80) | PAG-2 (21) | Q-1 (6) | PGMEA (1890) | GBL (210) |
| | 1-3 | CR-03 | P-1 (80) | PAG-1 (19) | Q-2 (9) | PGMEA (1890) | GBL (210) |

In Table 1, the hypervalent iodine compound (I-1-1 to I-1-3, I-2-1), carboxylic acid (CA-1 to CA-8) and solvent are identified below.

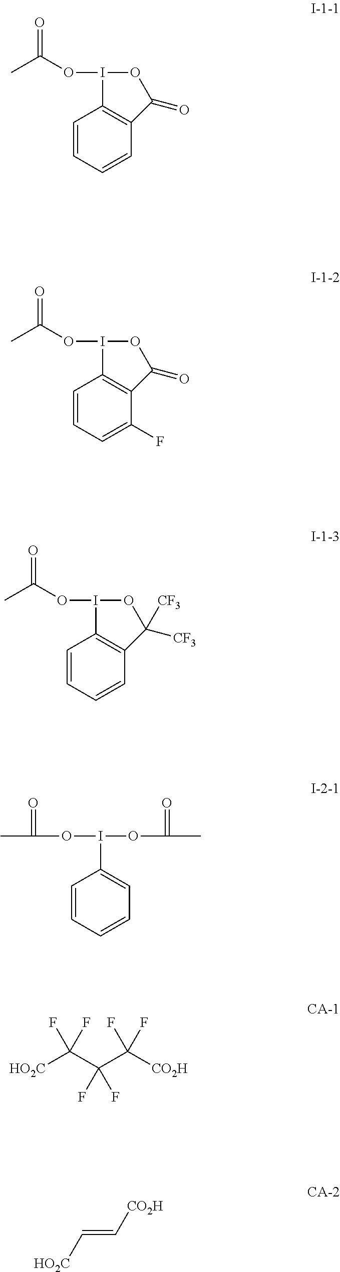 [SMILES: CC(=O)OI1OC(=O)c2ccccc21 ; CC(=O)OI1OC(=O)c2c(F)cccc21 ; CC(=O)OI1OC(C(F)(F)F)(C(F)(F)F)c2ccccc21 ; CC(=O)OI(OC(C)=O)c1ccccc1 ; O=C(O)C(F)(F)C(F)(F)C(F)(F)C(=O)O ; O=C(O)/C=C/C(=O)O]

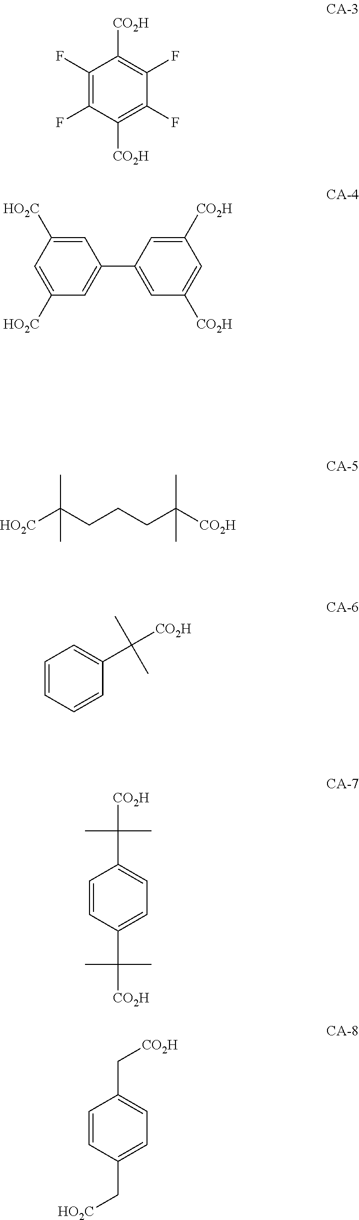 [SMILES: O=C(O)c1c(F)c(F)c(C(=O)O)c(F)c1F ; O=C(O)c1cc(C(=O)O)cc(-c2cc(C(=O)O)cc(C(=O)O)c2)c1 ; CC(C)(CCCC(C)(C)C(=O)O)C(=O)O ; CC(C)(C(=O)O)c1ccccc1 ; CC(C)(C(=O)O)c1ccc(C(C)(C)C(=O)O)cc1 ; O=C(O)Cc1ccc(CC(=O)O)cc1]

### Solvent:

PGMEA (propylene glycol monomethyl ether acetate)
AcOH (acetic acid)
GBL (γ-butyrolactone)

In Table 2, the base polymer (P-1), photoacid generator (PAG-1 and PAG-2), and sensitivity modifier (Q-1 and Q-2) are identified below. It is noted that the Mw of the base polymer is as measured by GPC versus polystyrene standards using THF solvent.

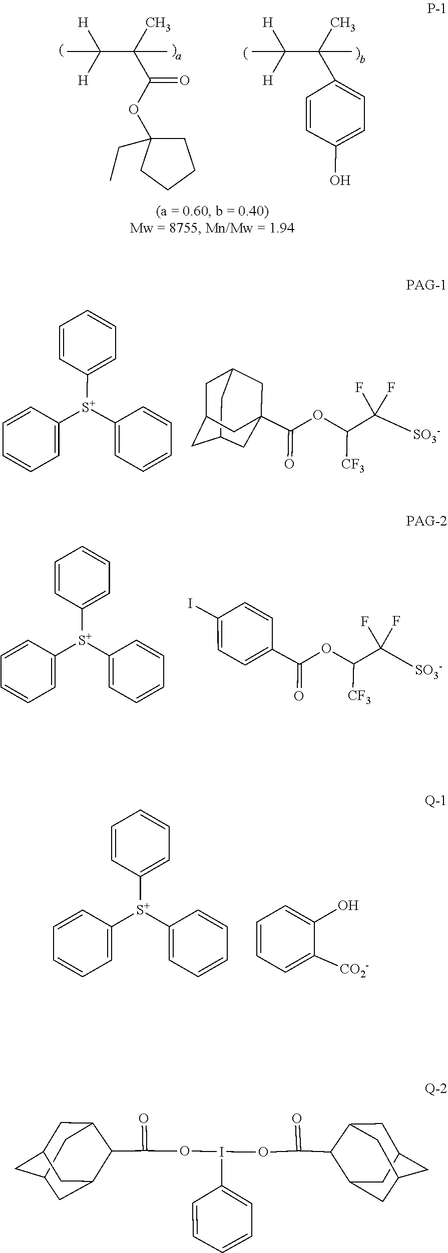

### [2] EUV Lithography Test

### Examples 2-1 to 2-10 and Comparative Examples 2-1 to 2-3

Each of the resist compositions (R-01 to R-10, CR-01 to CR-03) was spin coated on a silicon substrate having an antireflective film of 60 nm thick (DUV-42 by Nissan Chemical Co., Ltd.) and baked (PAB) on a hotplate at the temperature shown in Table 3 for 60 seconds to form a resist film of 140 nm thick. Using an EUV scanner NXE3400 (ASML, NA 0.33, σ 0.9, 90° dipole illumination), the resist film was exposed to EUV through a mask bearing a 40-nm 1:1 line-and-space (LS) pattern. The resist film was baked (PEB) on a hotplate at the temperature shown in Table 3 for 60 seconds.

After the PEB, dry etching was carried out in a dry etching system Telius (Tokyo Electron) under the following conditions.
Chamber pressure: 12.0 Pa
RF power: 600 W
Bias power: 50 W
Stage temperature: 25° C.
O₂ gas flow rate: 20 sccm
N₂ gas flow rate: 400 sccm
Time: 30 sec

The resist film and the antireflective film in the exposed region were etched or reduced in thickness by dry etching until the silicon substrate surface was exposed.

The 40-nm LS pattern was observed under CD-SEM (CG-6300, Hitachi High-Technologies Corp.). The optimum dose (Eop, mJ/cm²) which provided a 40-nm 1:1 LS pattern was determined and reported as sensitivity. After the wafer was sectioned, the cross-sectional profile of the 40-nm LS pattern was observed under SEM (S-4800, Hitachi High-Technologies Corp.). The results are shown in Table 3.

TABLE 3

| | | Resist | PAB/PEB temp. | Sensitivity | | |
|---|---|---|---|---|---|---|
| | | composition | (° C.) | (mJ/cm²) | Pattern tone | Cross-sectional profile |
| Example | 2-1 | R-01 | 100/100 | 45 | negative | rectangular |
| | 2-2 | R-02 | 100/100 | 50 | negative | rectangular |
| | 2-3 | R-03 | 100/100 | 45 | negative | rectangular |
| | 2-4 | R-04 | 100/100 | 50 | negative | rectangular |
| | 2-5 | R-05 | 100/100 | 55 | negative | rectangular |
| | 2-6 | R-06 | 100/100 | 60 | negative | rectangular |
| | 2-7 | R-07 | 100/100 | 60 | positive | rectangular |
| | 2-8 | R-08 | 100/100 | 60 | positive | rectangular |
| | 2-9 | R-09 | 100/100 | 45 | positive | rectangular |
| | 2-10 | R-10 | 100/100 | 50 | positive | rectangular |
| Comparative | 2-1 | CR-01 | 105/90 | 72 | positive | line pattern vanished |
| Example | 2-2 | CR-02 | 105/90 | 75 | positive | line pattern vanished |
| | 2-3 | CR-03 | 105/90 | 75 | positive | line pattern vanished |

It is evident from Table 3 that the resist compositions comprising a hypervalent iodine compound and a carboxylic acid within the scope of the invention form patterns through development by dry etching. In contrast, when the chemically amplified resist compositions of Comparative Examples were used, the patterns vanished after dry etching, indicating a failure to establish a substantial difference in etching rate between exposed and unexposed regions. In the case of the resist compositions comprising a hypervalent iodine compound and a carboxylic acid, either positive or negative tone patterns may be formed by a proper choice of the carboxylic acid. The development by dry etching enables to form patterns having a high aspect ratio and high resolution because the pattern collapse which is caused by the stress generated during spin drying in solution development is avoided.

Japanese Patent Application No. 2024-059982 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist pattern forming process comprising the steps of:
(i) applying a resist composition onto a substrate or a substrate having an underlying film deposited thereon to form a resist film thereon, the resist composition comprising at least one hypervalent iodine compound selected from a hypervalent iodine compound having the formula (1) and a hypervalent iodine compound having the formula (2), a carboxylic acid, and a solvent,
(ii) exposing the resist film to high-energy radiation,
(iii) baking the exposed resist film, and
(iv) dry etching the baked resist film for development to form a resist pattern, 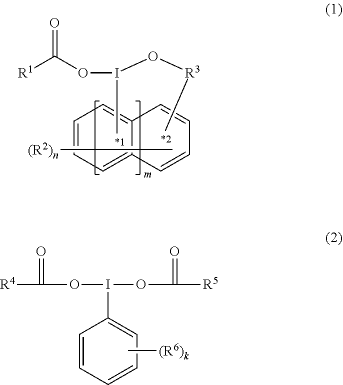
wherein m is 0 or 1, n is an integer of 0 to 4 when m=0 and an integer of 0 to 6 when m=1, k is an integer of 0 to 5,
R¹ is halogen or a C₁-C₁₀ hydrocarbyl group which may contain a heteroatom,
R² is halogen or a C₁-C₄₀ hydrocarbyl group which may contain a heteroatom; when n is 2 or more, a plurality of R² may be identical or different and a plurality of R² may bond together to form a ring with the carbon atoms on the aromatic ring to which they are attached,
R³ is carbonyl or a C₁-C₁₀ hydrocarbylene group which may contain a heteroatom,
*1 and *2 each designate a point of attachment to the carbon atom on the aromatic ring in the formula, *1 and *2 are attached to vicinal carbon atoms on the aromatic ring,
R⁴ and R⁵ are each independently halogen or a C₁-C₁₀ hydrocarbyl group which may contain a heteroatom, R⁴ and R⁵ may bond together to form a ring with the carbon atoms to which they are attached and the intervenient atoms, and
R⁶ is halogen or a C₁-C₄₀ hydrocarbyl group which may contain a heteroatom; when k is 2, 3, 4 or 5, a plurality of R⁶ may be identical or different and a plurality of R⁶ may bond together to form a ring with the carbon atoms on the aromatic ring to which they are attached.

2. The process of claim 1 wherein the carboxylic acid has the formula (3): 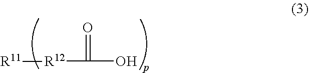
wherein p is an integer of 1 to 4,
R¹¹ is a C₁-C₄₀ p-valent hydrocarbon group or C₂-C₄₀ p-valent heterocyclic group, R¹¹ may also be an ether bond, carbonyl group, azo group, thioether bond, carbonate bond, carbamate bond, sulfinyl group or sulfonyl group when p=2, some or all of the hydrogen atoms in the p-valent hydrocarbon group or p-valent heterocyclic group may be substituted by a heteroatom-containing moiety, and some —CH₂— in the p-valent hydrocarbon group may be replaced by a heteroatom-containing moiety,
R¹² is a single bond or C₁-C₂₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety, and a plurality of R¹² may be identical or different when p=2, 3 or 4.

3. The process of claim 1 wherein the high-energy radiation is i-line, KrF excimer laser, ArF excimer laser, EB or EUV.

4. The process of claim 1 wherein the dry etching step (iv) is carried out using a gas containing at least one of oxygen and tetrafluoromethane.
